(19) United States
(12) Patent Application Publication
(10) Pub. No.: US 2018/0259850 A1
(43) Pub. Date: Sep. 13, 2018

(54) METHOD FOR FORMING PATTERNED CURED FILM, PHOTOSENSITIVE COMPOSITION, DRY FILM, AND METHOD FOR PRODUCING PLATED SHAPED ARTICLE

(71) Applicant: TOKYO OHKA KOGYO CO., LTD., Kawasaki-shi (JP)

(72) Inventors: Makiko IRIE, Kawasaki-shi (JP); Aya MOMOZAWA, Kawasaki-shi (JP)

(21) Appl. No.: 15/909,127

(22) Filed: Mar. 1, 2018

(30) Foreign Application Priority Data
Mar. 10, 2017 (JP) 2017-046763
Mar. 10, 2017 (JP) 2017-046764

(51) Int. Cl. G03F 7/00; G03F 7/022; H05B 33/28; G02B 5/22; B82Y 10/00; G03F 7/075; G03F 7/023; C09B 23/14; G03F 7/038

(52) U.S. Cl. CPC G03F 7/0035; G03F 7/0226; H05B 33/28; G02B 5/22; G03F 7/0382; G03F 7/0002; G03F 7/075; G03F 7/0233; C09B 23/146; B82Y 10/00

(57) ABSTRACT

A method for forming a patterned cured film using a negative photosensitive composition. The composition includes a photopolymerizable compound and a photopolymerization initiator including an oxime ester compound of a specific structure having a 9,9-disubstituted fluorenyl group which is used for formation of a thick film resist pattern. The composition is mixed with an alkali-soluble resin which is a polymer of a monomer having an unsaturated double bond and includes a unit derived from a monomer having an aromatic group.

This application claims priority to Japanese Patent Application Nos. 2017-046763 and 2017-046764, both filed Mar. 10, 2017, entire the contents of which are incorporated herein by reference.

### BACKGROUND OF THE INVENTION

### Field of the Invention

The present invention relates to a photosensitive composition, a dry film formed of the photosensitive composition, a method for forming a patterned cured film using the photosensitive composition, and a method for producing a plated shaped article using a substrate with a patterned cured film formed by the method as a mold for formation of a plated shaped article.

### Related Art

Photofabrication is now the mainstream of microfabrication technology. Photofabrication is a generic term for the technology used for manufacturing various precision components such as semiconductor packages by coating a photosensitive composition on a surface of a processing target to form a photosensitive layer, patterning the photoresist layer using photolithography technology, and then performing electroforming or the like based mainly on chemical etching, electrolytic etching, or electroplating using the patterned photosensitive layer (resist pattern) as a mask.

In recent years, high density packaging technology has progressed in semiconductor packages along with downsizing electronics devices, and an increase in package density has been developed on the basis of mounting multi-pin thin film in packages, miniaturizing of package size, two-dimensional packaging technology in flip-tip systems or three-dimensional packaging technology. In such high density packaging technology, connection terminals, including protruding electrodes (mounting terminals) known as bumps that protrude above the package or metal posts that extend from peripheral terminals on the wafer and connect rewiring with the mounting terminals, are disposed on a surface of a substrate with high precision.

A photoresist composition is sometimes used for the above-mentioned photofabrication. There has been proposed, as a photofabrication method using a photoresist composition, a method in which a coating film having, on an underlying metal layer including wirings, openings in which wirings are partially exposed, and a plated resist film for formation of a conductor are formed, and then electrolytic plating is performed using the underlying metal layer as a plating current path to form a conductor in the above-mentioned openings (Patent Document 1). In Patent Document 1, a plated resist film for formation of a conductor is formed using a negative dry film resist containing an acrylic resin.

Patent Document 1: Japanese Unexamined Patent Application, Publication No. 2008-084919

### SUMMARY OF THE INVENTION

When a thick film resist pattern is formed in not only photofabrication application but also various applications, desired resist pattern is usually a resist pattern in which portions removed by development (resist-free portions) have a rectangular sectional shape. However, for example, when forming a resist pattern having a film thickness of 80 μm or more, it is not easy for exposure light to sufficiently reach the bottom of a photosensitive composition layer during exposure, thus making it difficult to form a resist pattern with resist-free portions having a satisfactory rectangular sectional shape.

The present invention has been made in view of the foregoing problems, and an object of the invention is to provide a method for forming a patterned cured film using a negative photosensitive composition capable of forming a resist pattern with resist-free portions having a satisfactory rectangular sectional shape at a low exposure dose even when forming a thick film resist pattern having a film thickness of 80 μm or more, the photosensitive composition, a dry film formed of the photosensitive composition, a method for forming a patterned cured film using the photosensitive composition, and a method for producing a plated shaped article using a substrate with a patterned cured film formed by the method as a mold for formation of a plated shaped article.

The present inventors have found that the above problems can be solved by using a negative photosensitive composition, including (A) a photopolymerizable compound and (B) a photopolymerization initiator including an oxime ester compound of a specific structure having a 9,9-disubstituted fluorenyl group, for formation of a thick film resist pattern, and also by mixing a negative photosensitive composition including (A) a photopolymerizable compound and (B) a photopolymerization initiator including an oxime ester compound of a specific structure having a 9,9-disubstituted fluorenyl group with (C) an alkali-soluble resin which is a polymer of a monomer having an unsaturated double bond and includes a unit derived from a monomer having an aromatic group, and thus the present invention has been completed. Specifically, the present invention provides the following.

A first aspect of the present invention is directed to a method for forming a patterned cured film, in which the method includes laminating a photosensitive layer formed of a photosensitive composition on a metal surface of a substrate having the metal surface, exposing the photosensitive layer, and developing the photosensitive layer after exposure, in which the photosensitive layer has a thickness of 80 μm or more, the photosensitive composition includes (A) a photopolymerizable compound, and (B) a photopolymerization initiator, and the photopolymerization initiator (B) contains a compound represented by the following formula (1):

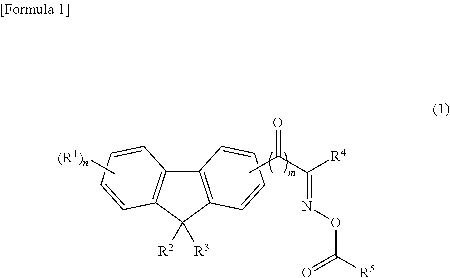

in which R¹ is a hydrogen atom, a nitro group, or a monovalent organic group, R² and R³ each are an optionally substituted chain alkyl group, an optionally substituted cyclic organic group, or a hydrogen atom, R² and R³ may be bonded to one another to form a ring, R⁴ is a monovalent organic group, R⁵ is a hydrogen atom, an optionally substituted alkyl group having 1 to 11 carbon atom, or an optionally substituted aryl group, n is an integer of 0 to 4, and m is 0 or 1.

A second aspect of the present invention is directed to a photosensitive composition including (A) a photopolymerizable compound, (B) a photopolymerization initiator, and (C) an alkali-soluble resin, in which the photopolymerization initiator (B) contains a compound represented by the following formula (1):

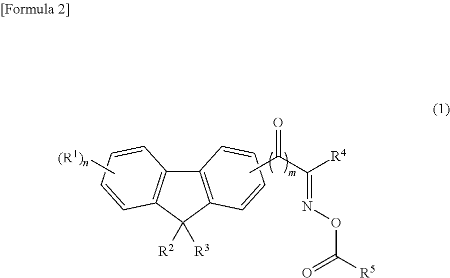

in which R¹ is a hydrogen atom, a nitro group, or a monovalent organic group, R² and R³ each are an optionally substituted chain alkyl group, an optionally substituted cyclic organic group, or a hydrogen atom, R² and R³ may be bonded to one another to form a ring, R⁴ is a monovalent organic group, R⁵ is a hydrogen atom, an optionally substituted alkyl group having 1 to 11 carbon atom, or an optionally substituted aryl group, n is an integer of 0 to 4, and m is 0 or 1, and (C) the alkali-soluble resin is a polymer of a monomer having an unsaturated double bond and includes a unit derived from a monomer having an aromatic group.

A third aspect of the present invention is directed to a dry film formed of the photosensitive composition according to the second aspect.

A fourth aspect of the present invention is directed to a method for forming a patterned cured film, in which the method includes: laminating a photosensitive layer formed of the photosensitive composition according to the second aspect on a metal surface of a substrate having the metal surface, exposing the photosensitive layer, and developing the photosensitive layer after exposure, in which the photosensitive layer has a thickness of 80 μm or more.

A fifth aspect of the present invention is directed to a method for producing a plated shaped article, in which the method includes plating a substrate with a patterned cured film formed by the method according to the first or fourth aspect as a mold for formation of a plated shaped article to form a plated shaped article in the mold.

According to the present invention, it is possible to provide a method for forming a patterned cured film using a negative photosensitive composition capable of forming a resist pattern with resist-free portions having a satisfactory rectangular sectional shape at a low exposure dose even when forming a thick film resist pattern having a film thickness of 80 μm or more, the photosensitive composition, a dry film formed of the photosensitive composition, a method for forming a patterned cured film using the photosensitive composition, and a method for producing a plated shaped article using a substrate with a patterned cured film formed by the method as a mold for formation of a plated shaped article.

### DETAILED DESCRIPTION OF THE INVENTION

### «Method for Forming Patterned Cured Film»

The method for forming a patterned cured film (hereinafter also referred to as the “resist pattern”) according to the first aspect includes: laminating a photosensitive layer formed of a photosensitive composition on a substrate having a metal surface, exposing the photosensitive layer, and developing the photosensitive layer after exposure. The method for forming a patterned cured film (resist pattern) according to the fourth aspect includes laminating a photosensitive layer formed of the photosensitive composition according to the second aspect on a metal surface of a substrate having the metal surface; exposing the photosensitive layer; and developing the photosensitive layer after exposure.

In the first and fourth aspects, the photosensitive layer has a thickness of 80 μm or more. A resist pattern is formed using a photosensitive layer having such thickness, and then plating is performed using the thus formed resist pattern as a mold for production of a plated shaped article, whereby, it is possible to form bumps and metal posts each having a desired size on a metal surface of a substrate.

In general, when a thick photosensitive layer having a 80 μm or more is subjected to exposure and development to form a resist pattern, it is not easy for exposure light to reach the bottom of the photosensitive layer, thus making it difficult to form a resist pattern with resist-free portions having a satisfactory rectangular sectional shape. However, according to the above method, by forming a photosensitive layer for formation of a resist pattern using a photosensitive composition including a specific photopolymerization initiator (B), as mentioned below, it is possible to form a resist pattern with resist-free portions having a satisfactory rectangular sectional shape even if a thick photosensitive layer having a 80 μm or more is formed.

Various steps included in the method for forming a patterned cured film will be sequentially described below. Hereinafter, lamination of a photosensitive layer formed of a photosensitive composition to a metal surface of a substrate having a metal surface is also referred to as the lamination step. Exposure to a photosensitive layer formed by the lamination step is also referred to as the exposure step. Development of the photosensitive layer after exposure is also referred to as the development step.

### <Lamination Step>

In the lamination step, a photosensitive layer formed of a photosensitive composition is laminated on a metal surface of a substrate having the metal surface. The photosensitive layer has a thickness of 80 μm or more, preferably 80 to 500 μm, and more preferably 120 to 300 μm.

A photosensitive composition for formation of a photosensitive layer includes (A) a photopolymerizable compound, and (B) a photopolymerization initiator. The photosensitive composition may or may not include (C) an alkali-soluble resin. Materials used in the lamination step will be described below. Specific method of the lamination step will be mentioned later.

### «Photosensitive Composition»

As mentioned above, the photosensitive composition used for formation of the photosensitive layer includes (A) a photopolymerizable compound and (B) a photopolymerization initiator, and may optionally include (C) an alkali-soluble resin. The photopolymerization initiator (B) includes the below-mentioned compound of a specific structure.

The present invention also relates to a photosensitive composition including (A) a photopolymerizable compound, (B) a photopolymerization initiator, and (C) an alkali-soluble resin, in which (C) the alkali-soluble resin is a polymer of a monomer having an unsaturated double bond and includes a unit derived from a monomer having an aromatic group. The photosensitive composition according to the second aspect includes (A) a photopolymerizable compound, (B) a photopolymerization initiator, and (C) an alkali-soluble resin, in which (C) the alkali-soluble resin is a polymer of a monomer having an unsaturated double bond and includes a unit derived from a monomer having an aromatic group.

In general, when a thick photosensitive layer having a 80 μm or more is subjected to exposure and development to form a patterned cured film (hereinafter also referred to as the “resist pattern”), it is not easy for exposure light to reach the bottom of the photosensitive layer, thus making it difficult to form a resist pattern with resist-free portions having a satisfactory rectangular sectional shape. However, when using the above photosensitive composition, as mentioned below, even if a thick photosensitive layer having a 80 μm or more is formed, it is possible to form a resist pattern with resist-free portions having a satisfactory rectangular sectional shape.

Essential or optional components included in the photosensitive composition, and a method for preparing a photosensitive composition will be described below.

### <(A) Photopolymerizable Compound>

There is no particular limitation on the photopolymerizable compound (A) (hereinafter also referred to as the component (A)) included in the photosensitive composition, and it is possible to use conventionally known photopolymerizable compounds. Among these, a resin or monomer having an ethylenically unsaturated group is preferable, and it is more preferable to use them in combination. Use of a resin having an ethylenically unsaturated group in combination with a monomer having an ethylenically unsaturated group enables an improvement in curability of the photosensitive composition, thus making it easy to form a pattern.

### (Resin Having Ethylenically Unsaturated Group)

Examples of the resin having an ethylenically unsaturated group include oligomers obtained by polymerization of (meth)acrylic acid, fumaric acid, maleic acid, monomethyl fumarate, monoethyl fumarate, 2-hydroxyethyl (meth)acrylate, ethylene glycol monomethyl ether (meth)acrylate, ethylene glycol monoethyl ether (meth)acrylate, glycerol (meth)acrylate, (meth)acrylamide, acrylonitrile, methacrylonitrile, methyl (meth)acrylate, ethyl (meth)acrylate, isobutyl (meth)acrylate, 2-ethylhexyl (meth)acrylate, benzyl (meth)acrylate, ethylene glycol di(meth)acrylate, diethylene glycol di(meth)acrylate, triethylene glycol di(meth)acrylate, tetraethylene glycol di(meth)acrylate, butylene glycol di(meth)acrylate, propylene glycol di(meth)acrylate, trimethylolpropane tri(meth)acrylate, tetramethylolpropane tetra(meth)acrylate, pentaerythritol tri(meth)acrylate, pentaerythritol tetra(meth)acrylate, dipentaerythritol penta(meth)acrylate, dipentaerythritol hexa(meth)acrylate, 1,6-hexanediol di(meth)acrylate, cardoepoxy diacrylate, and the like; polyester (meth)acrylate, which is obtained by reacting a polyester prepolymer obtained by fusing polyhydric alcohols with a monobasic acid or a polybasic acid, with (meth)acrylic acid; polyurethane (meth)acrylate obtained by reacting a polyol with a compound having two isocyanate groups, followed by a reaction with (meth)acrylic acid; and an epoxy (meth)acrylate resin obtained by reacting an epoxy resin such as a bisphenol A type epoxy resin, a bisphenol F type epoxy resin, a bisphenol S type epoxy resin, a phenol or cresol novolac type epoxy resin, a resol type epoxy resin, a triphenolmethane type epoxy resin, a polycarboxylic acid polyglycidyl ester, a polyol polyglycidyl ester, an aliphatic or alicyclic epoxy resin, an amine epoxy resin, or a dihydroxybenzene type epoxy resin with (meth)acrylic acid. It is also possible to suitably use a resin obtained by reacting an epoxy (meth)acrylate resin with a polybasic anhydride. As used herein, “(meth)acryl” means “acryl or methacryl”.

It is possible to suitably use, as the resin having an ethylenically unsaturated group, a resin obtained by reacting a reaction product of an epoxy compound and an unsaturated group-containing carboxylic acid compound with a polybasic anhydride.

Among these, a compound represented by the following formula (a1) is preferable. This compound represented by the formula (a1) is preferable because of its high photocurability.

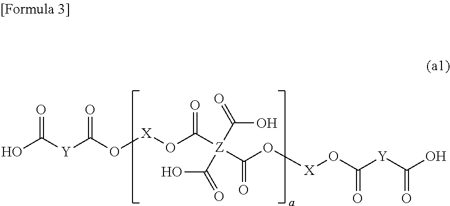

In the above formula (a1), X represents a group represented by the following formula (a2).

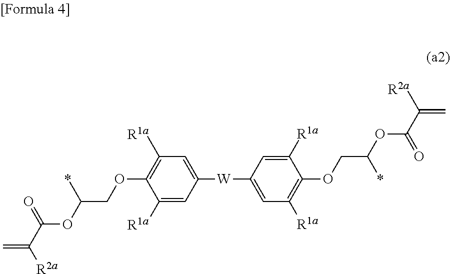

In the above formula (a2), R^{1a} each independently represents a hydrogen atom, a hydrocarbon group having 1 to 6 carbon atoms, or a halogen atom, R^{2a} each independently represents a hydrogen atom or a methyl group, and W represents a single bond or a group represented by a structural formula (a3) below. In the formula (a2) and the structural formula (a3), “*” means the end of a bond of a divalent group.

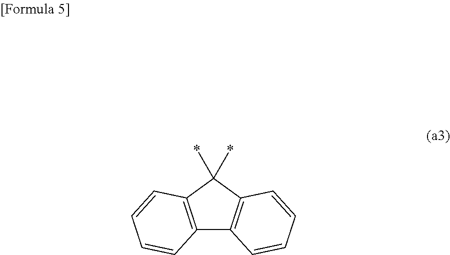 [SMILES: *C1(*)c2ccccc2-c2ccccc21]

In the above formula (a1), Y represents a residue in which an anhydride group (—CO—O—CO—) is removed from dicarboxylic anhydride. Examples of the dicarboxylic anhydride include maleic anhydride, succinic anhydride, itaconic anhydride, phthalic anhydride, tetrahydrophthalic anhydride, hexahydrophthalic anhydride, methyl endo-methylene-tetrahydrophthalic anhydride, chlorendic anhydride, methyltetrahydrophthalic anhydride, glutaric anhydride, and the like.

In the above formula (a1), Z represents a residue in which two anhydride groups are removed from tetracarboxylic dianhydride. Examples of the tetracarboxylic dianhydride include pyromellitic anhydride, benzophenonetetracarboxylic dianhydride, biphenyltetracarboxylic dianhydride, biphenyl ether tetracarboxylic dianhydride, and the like. In the above formula (a1), a represents an integer of 0 to 20.

An acid value of the resin having an ethylenically unsaturated group is preferably 10 to 150 mgKOH/g, and more preferably 70 to 110 mgKOH/g, in terms of the solid content of the resin. It is preferable that sufficient solubility in developing solution can be obtained by adjusting the acid value at 10 mgKOH/g or more. It is preferable that sufficient curability can be obtained and surface property can be improved by adjusting the acid value at 150 mgKOH/g or less.

A mass average molecular weight of the resin having an ethylenically unsaturated group is preferably 1,000 to 40,000, and more preferably 2,000 to 30,000. It is preferable that satisfactory heat resistance and film strength can be obtained by adjusting the mass average molecular weight at 1,000 or more. It is preferable that satisfactory developability can be obtained by adjusting the mass average molecular weight at 40,000 or less.

### (Monomer Having Ethylenically Unsaturated Group)

The monomer having an ethylenically unsaturated group includes a monofunctional monomer and a polyfunctional monomer. The monofunctional monomer and the polyfunctional monomer will be sequentially described below.

Examples of the monofunctional monomer include (meth)acrylamide, methylol(meth)acrylamide, methoxymethyl(meth)acrylamide, ethoxymethyl(meth)acrylamide, propoxymethyl(meth)acrylamide, butoxymethoxymethyl(meth)acrylamide, N-methylol(meth)acrylamide, N-hydroxymethyl(meth)acrylamide, (meth)acrylic acid, fumaric acid, maleic acid, maleic anhydride, itaconic acid, itaconic anhydride, citraconic acid, citraconic anhydride, crotonic acid, 2-acrylamide-2-methylpropanesulfonic acid, tert-butylacrylamidesulfonic acid, methyl (meth)acrylate, ethyl (meth)acrylate, butyl (meth)acrylate, 2-ethylhexyl (meth)acrylate, cyclohexyl (meth)acrylate, 2-hydroxyethyl (meth)acrylate, 2-hydroxypropyl (meth)acrylate, 2-hydroxybutyl (meth)acrylate, 2-phenoxy-2-hydroxypropyl (meth)acrylate, 2-(meth)acryloyloxy-2-hydroxypropyl phthalate, glycerin mono(meth)acrylate, tetrahydrofurfuryl (meth)acrylate, dimethylaminoethyl (meth)acrylate, glycidyl (meth)acrylate, 2,2,2-trifluoroethyl (meth)acrylate, 2,2,3,3-tetrafluoropropyl (meth)acrylate, a half (meth)acrylate of a phthalic acid derivative, and the like. These monofunctional monomers may be used alone, or two or more monofunctional monomers may be used in combination.

Examples of the polyfunctional monomer include difunctional monomers such as ethylene glycol di(meth)acrylate, diethylene glycol di(meth)acrylate, tetraethylene glycol di(meth)acrylate, propylene glycol di(meth)acrylate, polypropylene glycol di(meth)acrylate, butylene glycol di(meth)acrylate, neopentyl glycol di(meth)acrylate, 1,6-hexane glycol di(meth)acrylate, glycerin di(meth)acrylate, pentaerythritol di(meth)acrylate, phthalic acid diglycidyl ester di(meth)acrylate, 2,2-bis(4-(meth)acryloxydiethoxyphenyl)propane, 2,2-bis(4-(meth)acryloxypolyethoxyphenyl)propane, 2-hydroxy-3-(meth)acryloyloxypropyl (meth)acrylate, ethylene glycol diglycidyl ether di(meth)acrylate, diethylene glycol diglycidyl ether di(meth)acrylate, methylenebis(meth)acrylamide, urethane (meth)acrylate (i.e., a reaction product of tolylene diisocyanate, trimethylhexamethylene diisocyanate, or hexamethylene diisocyanate, and 2-hydroxyethyl (meth)acrylate), (meth)acrylamide methylene ether, tricyclodecanediol di(meth)acrylate, and ethoxylated isocyanuric acid di(meth)acrylate; polyfunctional monomers such as trimethylolpropane tri(meth)acrylate, ethoxylated isocyanuric acid di(meth)acrylate, pentaerythritol triacrylate, pentaerythritol tetraacrylate, dipentaerythritol pentaacrylate, dipentaerythritol hexaacrylate, pentaerythritol tri(meth)acrylate, pentaerythritol tetra(meth)acrylate, dipentaerythritol penta(meth)acrylate, dipentaerythritol hexa(meth)acrylate, glycerin triacrylate, glycerin polyglycidyl ether poly(meth)acrylate, and a fused product of polyhydric alcohol and N-methylol(meth)acrylamide; and trifunctional or higher polyfunctional monomers such as triacrylformal; and difunctional monomers are particularly preferable. These polyfunctional monomers may be used alone, or two or more polyfunctional monomers may be used in combination.

The resist pattern formed of the above-mentioned photosensitive composition is preferably used as a mold for formation of a plated shaped article, as mentioned below. However, the resist pattern used as the mold is peeled off from the substrate after plating. Here, when the photosensitive composition includes, as the photopolymerizable compound (A), a difunctional monomer, curing due to exposure of the photosensitive layer hardly proceeds, excessively. Therefore, it is easy for the resist pattern used as the mold to be peeled off after plating.

The content of the photopolymerizable compound as the component (A) is preferably 10 to 99.9 parts by mass based on 100 parts by mass of the total solid content of the photosensitive composition. It is easy to form a cured film having excellent heat resistance, chemical resistance, and mechanical strength by setting the content of the component (A) at 10 parts by mass or more based on 100 parts by mass of the total solid content using the photosensitive composition.

### <(B) Photopolymerization Initiator>

The photosensitive composition includes (B) a photopolymerization initiator (hereinafter also referred to as the component (B)) containing a compound represented by the following formula (1). The photosensitive composition is extremely excellent in sensitivity because of containing the compound represented by the following formula (1) as the photopolymerization initiator (B). Therefore, it is easy for the photosensitive composition containing the compound represented by the following formula (1) as the component (B) to form a resist pattern with resist-free portions having a satisfactory rectangular sectional shape at a low exposure dose regardless of a large film thickness.

It is desired for various patterns formed on various substrates to have excellent water resistance that prevents detachment of the patterns from the substrate due to moisture and the like. When using the photosensitive composition including the photopolymerization initiator (B) containing a compound represented by the following formula (1), it is easy to form a resist pattern having excellent water resistance, which is scarcely detached from the substrate even if the pattern is contacted with water.

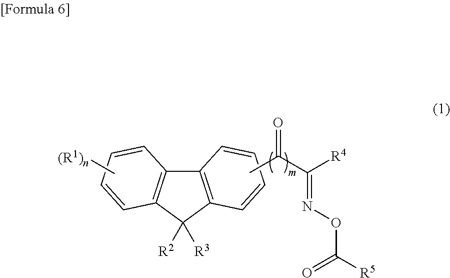

in which R¹ is a hydrogen atom, a nitro group, or a monovalent organic group, R² and R³ each are an optionally substituted chain alkyl group, an optionally substituted cyclic organic group, or a hydrogen atom, R² and R³ may be bonded to one another to form a ring, R⁴ is a monovalent organic group, R⁵ is a hydrogen atom, an optionally substituted alkyl group having 1 to 11 carbon atoms, or an optionally substituted aryl group, n is an integer of 0 to 4, and m is 0 or 1.

In the formula (1), R¹ is a hydrogen atom, a nitro group, or a monovalent organic group. R¹ is bonded to a 6-membered aromatic ring, which is different from a 6-membered aromatic ring to be bonded to a group represented by —(CO)ₘ—, on a fluorene ring in the formula (1). In the formula (1), a binding site for a fluorene ring of R¹ is not particularly limited. When the compound represented by the formula (1) has one or more R¹ (s), one of one or more R¹ (s) is preferably bonded at the 2-position in the fluorene ring since it is easy to synthesize the compound represented by the formula (1). When plural R1(s) are present, plural R¹(s) may be the same as or different from each other.

When R¹ is an organic group, R¹ is not particularly limited as long as the object of the present invention is not inhibited, and is appropriately selected from various organic groups. When R¹ is an organic group, suitable examples include an alkyl group, an alkoxy group, an cycloalkyl group, an cycloalkoxy group, a saturated aliphatic acyl group, an alkoxycarbonyl group, a saturated aliphatic acyloxy group, an optionally substituted phenyl group, an optionally substituted phenoxy group, an optionally substituted benzoyl group, an optionally substituted phenoxycarbonyl group, an optionally substituted benzoyloxy group, an optionally substituted phenylalkyl group, an optionally substituted naphthyl group, an optionally substituted naphthoxy group, an optionally substituted naphthoyl group, an optionally substituted naphthoxycarbonyl group, an optionally substituted naphthoyloxy group, an optionally substituted naphthylalkyl group, an optionally substituted heterocyclyl group, an optionally substituted heterocyclylcarbonyl group, an amino group substituted with one or more organic groups, a morpholin-1-yl group, and a piperazin-1-yl group.

When R¹ is an alkyl group, the number of carbon atoms of the alkyl group is preferably 1 to 20, and more preferably 1 to 6. When R¹ is an alkyl group, the alkyl group may be either one of a straight chain or branched chain alkyl group. When R¹ is an alkyl group, specific examples include a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, a tert-pentyl group, an n-hexyl group, an n-heptyl group, an n-octyl group, an isooctyl group, a sec-octyl group, a tert-octyl group, an n-nonyl group, an isononyl group, an n-decyl group, and an isodecyl group. When R¹ is an alkyl group, the alkyl group may contain an ether bond (—O—) in the carbon chain. Examples of the alkyl group having an ether bond in the carbon chain include a methoxyethyl group, an ethoxyethyl group, a methoxyethoxyethyl group, an ethoxyethoxyethyl group, a propyloxyethoxyethyl group, and a methoxypropyl group.

When R¹ is an alkoxy group, the number of carbon atoms of the alkoxy group is preferably 1 to 20, and more preferably 1 to 6. When R¹ is an alkoxy group, the alkoxy group may be either one of a straight chain or branched chain alkoxy group. When R¹ is an alkoxy group, specific examples include a methoxy group, an ethoxy group, an n-propyloxy group, an isopropyloxy group, an n-butyloxy group, an isobutyloxy group, a sec-butyloxy group, a tert-butyloxy group, an n-pentyloxy group, an isopentyloxy group, a sec-pentyloxy group, a tert-pentyloxy group, an n-hexyloxy group, an n-heptyloxy group, an n-octyloxy group, an isooctyloxy group, a sec-octyloxy group, a tert-octyloxy group, an n-nonyloxy group, an isononyloxy group, an n-decyloxy group, and an isodecyloxy group. When R¹ is an alkoxy group, the alkoxy group may include an ether bond (—O—) in the carbon chain. Examples of the alkoxy group having an ether bond in the carbon chain include a methoxyethoxy group, an ethoxyethoxy group, a methoxyethoxyethoxy group, an ethoxyethoxyethoxy group, a propyloxyethoxyethoxy group, and a methoxypropyloxy group.

When R¹ is a cycloalkyl group or a cycloalkoxy group, the number of carbon atoms of the cycloalkyl group or cycloalkoxy group is preferably 3 to 10, and more preferably 3 to 6. When R¹ is a cycloalkyl group, specific examples include a cyclopropyl group, a cyclobutyl group, a cyclopentyl group, a cyclohexyl group, a cycloheptyl group, and a cyclooctyl group. When R¹ is a cycloalkoxy group, specific examples include a cyclopropyloxy group, a cyclobutyloxy group, a cyclopentyloxy group, a cyclohexyloxy group, a cycloheptyloxy group, and a cyclooctyloxy group.

When R¹ is a saturated aliphatic acyl group or a saturated aliphatic acyloxy group, the number of carbon atoms of the saturated aliphatic acyl group or saturated aliphatic acyloxy group is preferably 2 to 21, and more preferably 2 to 7. When R¹ is a saturated aliphatic acyl group, specific examples include an acetyl group, a propanoyl group, an n-butanoyl group, a 2-methylpropanoyl group, an n-pentanoyl group, a 2,2-dimethylpropanoyl group, an n-hexanoyl group, an n-heptanoyl group, an n-octanoyl group, an n-nonanoyl group, an n-decanoyl group, an n-undecanoyl group, an n-dodecanoyl group, an n-tridecanoyl group, an n-tetradecanoyl group, an n-pentadecanoyl group, and an and n-hexadecanoyl group. When R¹ is a saturated aliphatic acyloxy group, specific examples include an acetyloxy group, a propanoyloxy group, an n-butanoyloxy group, a 2-methylpropanoyloxy group, an n-pentanoyloxy group, a 2,2-dimethylpropanoyloxy group, an n-hexanoyloxy group, an n-heptanoyloxy group, an n-octanoyloxy group, an n-nonanoyloxy group, an n-decanoyloxy group, an n-undecanoyloxy group, an n-dodecanoyloxy group, an n-tridecanoyloxy group, an n-tetradecanoyloxy group, an n-pentadecanoyloxy group, and an n-hexadecanoyloxy group.

When R¹ is an alkoxycarbonyl group, the number of carbon atoms of the alkoxycarbonyl group is preferably 2 to 20, and more preferably 2 to 7. When R¹ is an alkoxycarbonyl group, specific examples include a methoxycarbonyl group, an ethoxycarbonyl group, an n-propyloxycarbonyl group, an isopropyloxycarbonyl group, an n-butyloxycarbonyl group, an isobutyloxycarbonyl group, a sec-butyloxycarbonyl group, a tert-butyloxycarbonyl group, an n-pentyloxycarbonyl group, an isopentyloxycarbonyl group, a sec-pentyloxycarbonyl group, a tert-pentyloxycarbonyl group, an n-hexyloxycarbonyl group, an n-heptyloxycarbonyl group, an n-octyloxycarbonyl group, an isooctyloxycarbonyl group, a sec-octyloxycarbonyl group, a tert-octyloxycarbonyl group, an n-nonyloxycarbonyl group, an isononyloxycarbonyl group, an n-decyloxycarbonyl group, and an isodecyloxycarbonyl group.

When R¹ is a phenylalkyl group, the number of carbon atoms of the phenylalkyl group is preferably 7 to 20, and more preferably 7 to 10. When R¹ is a naphthylalkyl group, the number of carbon atoms of the naphthylalkyl group is preferably 11 to 20, and more preferably 11 to 14. When R¹ is a phenylalkyl group, specific examples include a benzyl group, a 2-phenylethyl group, a 3-phenylpropyl group, and a 4-phenylbutyl group. When R¹ is a naphthylalkyl group, specific examples include an α-naphthylmethyl group, a β-naphthylmethyl group, a 2-(α-naphthyl)ethyl group, and a 2-(β-naphthyl)ethyl group. When R¹ is a phenylalkyl group or naphthylalkyl group, R¹ may further have a substituent on a phenyl group or a naphthyl group.

When R¹ is a heterocyclyl group, the heterocyclyl group is a 5- or 6-membered single ring containing one or more N, S, and O, or a heterocyclyl group in which such single rings are fused each other, or such a single ring is fused with a benzene ring. When the heterocyclyl group is a fused ring, the number of fused ring is 3 or less. The heterocyclyl group may be any one of an aromatic group (heteroaryl group) and a non-aromatic group. Examples of the heterocycle constituting the heterocyclyl group include furan, thiophene, pyrrole, oxazole, isoxazole, triazole, thiadiazole, isothiazole, imidazole, pyrazole, triazole, pyridine, pyrazine, pyrimidine, pyridazine, benzofuran, benzothiophene, indole, isoindole, indolizine, benzoimidazole, benzotriazole, benzoxazole, benzothiazole, carbazole, purine, quinoline, isoquinoline, quinazoline, phthalazine, cinnoline, quinoxaline, piperidine, piperazine, morpholine, piperidine, tetrahydropyran, and tetrahydrofuran. When R¹ is a heterocyclyl group, the heterocyclyl group may have a substituent.

When R¹ is a heterocyclylcarbonyl group, the heterocyclyl group included in the heterocyclylcarbonyl group is the same as that in a case where R¹ is a heterocyclyl group

When R¹ is an amino group substituted with one or two organic groups, suitable examples of the organic group include an alkyl group having 1 to 20 carbon atoms, a cycloalkyl group having 3 to 10 carbon atoms, a saturated aliphatic acyl group having 2 to 21 carbon atoms, an optionally substituted phenyl group, an optionally substituted benzoyl group, an optionally substituted phenylalkyl group having 7 to 20 carbon atoms, an optionally substituted naphthyl group, an optionally substituted naphthoyl group, an optionally substituted naphthylalkyl group having 11 to 20 carbon atoms, and a heterocyclyl group. Specific examples of suitable organic group are the same as those in R¹. Specific examples of the amino group substituted with one or two organic group include a methylamino group, an ethylamino group, a diethylamino group, an n-propylamino group, a di-n-propylamino group, an isopropylamino group, an n-butylamino group, a di-n-butylamino group, an n-pentylamino group, an n-hexylamino group, an n-heptylamino group, an n-octylamino group, an n-nonylamino group, an n-decylamino group, a phenylamino group, a naphthylamino group, an acetylamino group, an propanoylamino group, an n-butanoylamino group, an n-pentanoylamino group, an n-hexanoylamino group, an n-heptanoylamino group, an n-octanoylamino group, an n-decanoylamino group, a benzoylamino group, an α-naphthoylamino group, and a β-naphthoylamino group.

When an phenyl group, an naphthyl group, and a heterocyclyl group included in R¹ further have a substituent, examples of the substituent include an alkyl group having 1 to 6 carbon atoms, an alkoxy group having 1 to 6 carbon atoms, a saturated aliphatic acyl group having 2 to 7 carbon atoms, an alkoxycarbonyl group having 2 to 7 carbon atoms, a saturated aliphatic acyloxy group having 2 to 7 carbon atoms, a monoalkylamino group which has an alkyl group having 1 to 6 carbon atoms, a dialkylamino group which has an alkyl group having 1 to 6 carbon atoms, a morpholin-1-yl group, an piperazin-1-yl group, halogen, a nitro group, and a cyano group. When a phenyl group, a naphthyl group, and a heterocyclyl group included in R¹ further have a substituent, the number of substituents is not particularly limited as long as the object of the present invention is not inhibited, and is preferably 1 to 4. When a phenyl group, a naphthyl group, and a heterocyclyl group included in R¹ have plural substituents, plural substituents may be the same as or different each other.

Among the groups described above, R¹ is preferably a nitro group or a group represented by R⁶—CO— since sensitivity tends to be improved. R⁶ is not particularly limited as long as the object of the present invention is not inhibited, and can be selected from various organic groups. Examples of the group suitable as R⁶ include an optionally substituted alkyl group having 1 to 20 carbon atoms, an optionally substituted phenyl group, an optionally substituted naphthyl group, and an optionally substituted heterocyclyl group. Among these groups, R⁶ is particularly preferably a 2-methylphenyl group, a thiophen-2-yl group, or an α-naphthyl group. Since transparency tends to be improved, R¹ is preferably a hydrogen atom. When R¹ is a hydrogen atom, and R⁴ is a group represented by the formula (R4-2) mentioned below, transparency tends to be further improved.

In the formula (1), R² and R³ each are an optionally substituted chain alkyl group, an optionally substituted cyclic organic group, or a hydrogen atom. R² and R³ may be bonded to one another to form a ring. Among these groups, R² and R³ are preferably optionally substituted chain alkyl groups. When R² and R³ are optionally substituted chain alkyl groups, chain alkyl group may be any one of straight chain and branched chain alkyl groups.

When R² and R³ are chain alkyl groups having no substituent, the number of carbon atoms of the chain alkyl group is preferably 1 to 20, more preferably 1 to 10, and particularly preferably 1 to 6. When R² and R³ are chain alkyl groups, specific examples include a methyl group, an ethyl group, an n-propyl group, an isopropyl group, an n-butyl group, an isobutyl group, a sec-butyl group, a tert-butyl group, an n-pentyl group, an isopentyl group, a sec-pentyl group, a tert-pentyl group, an n-hexyl group, an n-heptyl group, an n-octyl group, an isooctyl group, a sec-octyl group, a tert-octyl group, an n-nonyl group, an isononyl group, an n-decyl group, and an isodecyl group. When R² and R³ are alkyl groups, the alkyl group may include an ether bond (—O—) in the carbon chain. Examples of the alkyl group having an ether bond in the carbon chain include a methoxyethyl group, an ethoxyethyl group, a methoxyethoxyethyl group, an ethoxyethoxyethyl group, a propyloxyethoxyethyl group, and a methoxypropyl group.

When R² and R³ are chain alkyl groups having a substituent, the number of carbon atoms of the chain alkyl group is preferably 1 to 20, more preferably 1 to 10, and particularly preferably 1 to 6. In this case, the number of carbon atoms of the substituent is not included in the number of carbon atoms of the chain alkyl group. The chain alkyl group having a substituent is preferably a straight chain alkyl group. There is no particular limitation on the substituent which may be possessed by the alkyl group as long as the object of the present invention is not inhibited. Suitable examples of the substituent include a cyano group, a halogen atom, a cyclic organic group, and an alkoxycarbonyl group. Examples of the halogen atom include a fluorine atom, a chlorine atom, a bromine atom, and an iodine atom. Among these, a fluorine atom, a chlorine atom, and a bromine atom are preferable. Examples of the cyclic organic group include a cycloalkyl group, an aromatic hydrocarbon group, and a heterocyclyl group. Specific examples of the cycloalkyl group are the same as suitable examples in the case where R¹ is a cycloalkyl group. Specific examples of the aromatic hydrocarbon group include a phenyl group, a naphthyl group, a biphenylyl group, an anthryl group, and a phenanthryl group. Specific examples of the heterocyclyl group are the same as suitable examples in the case where R¹ is a heterocyclyl group. When the substituent is an alkoxycarbonyl group, an alkoxy group contained in the alkoxycarbonyl group may be either one of straight chain or branched chain alkoxy group, and preferably a straight chain alkoxy group. The number of carbon atoms of the alkoxy group included in the alkoxycarbonyl group is preferably 1 to 10, and more preferably 1 to 6.

When the chain alkyl group has a substituent, the number of substituents is not particularly limited. The preferable number of substituents varies depending on the number of carbon atoms of the chain alkyl group. The number of substituents is typically 1 to 20, preferably 1 to 10, and more preferably 1 to 6.

When R² and R³ are cyclic organic groups, the cyclic organic group may be any one of an alicyclic group and an aromatic group. Examples of the cyclic organic group include an aliphatic cyclic hydrocarbon group, an aromatic hydrocarbon group, and a heterocyclyl group. When R² and R³ are cyclic organic groups, the substituent which may be possessed by the cyclic organic group is the same as that in the case where R² and R³ are chain alkyl groups.

When R² and R³ are aromatic hydrocarbon groups, the aromatic hydrocarbon group is preferably a phenyl group formed by bonding of plural benzene rings via a carbon-carbon bond, or a group formed by fusion of plural benzene rings. When the aromatic hydrocarbon group is a phenyl group, or a group formed by bonding or fusion of plural benzene rings, the number of benzene rings included in the aromatic hydrocarbon group is not particularly limited, and is preferably 3 or less, more preferably 2 or less, and particularly preferably 1. Suitable specific examples of the aromatic hydrocarbon group include a phenyl group, a naphthyl group, a biphenylyl group, an anthryl group, and a phenanthryl group.

When R² and R³ are aliphatic cyclic hydrocarbon groups, the aliphatic cyclic hydrocarbon group may be any one of monocyclic and polycyclic hydrocarbon groups. The number of carbon atoms of the aliphatic cyclic hydrocarbon group is not particularly limited, and is preferably 3 to 20, and more preferably 3 to 10. Examples of the monocyclic cyclic hydrocarbon group include a cyclopropyl group, a cyclobutyl group, a cyclopentyl group, a cyclohexyl group, a cycloheptyl group, a cyclooctyl group, a norbornyl group, an isobornyl group, a tricyclononyl group, a tricyclodecyl group, a tetracyclododecyl group, and an adamantyl group.

When R² and R³ are the heterocyclyl group, the heterocyclyl group is a 5- or 6-membered single ring including one or more N, S, and O, or a heterocyclyl group obtained by fusion of single rings, or fusion of a single ring with a benzene ring. When the heterocyclyl group is a fused ring, the number of rings to be fused is 3 or less. The heterocyclyl group may be any one of an aromatic group (heteroaryl group) and a non-aromatic group. Examples of the heterocycle constituting the heterocyclyl group include furan, thiophene, pyrrole, oxazole, isoxazole, triazole, thiadiazole, isothiazole, imidazole, pyrazole, triazole, pyridine, pyrazine, pyrimidine, pyridazine, benzofuran, benzothiophene, indole, isoindole, indolizine, benzoimidazole, benzotriazole, benzoxazole, benzothiazole, carbazole, purine, quinoline, isoquinoline, quinazoline, phthalazine, cinnoline, quinoxaline, piperidine, piperazine, morpholine, piperidine, tetrahydropyran, and tetrahydrofuran.

R² and R³ may be bonded to one another to form a ring. The group composed of the ring formed by R² and R³ is preferably a cycloalkylidene group. When R² and R³ are bonded to form a cycloalkylidene group, the ring constituting the cycloalkylidene group is preferably a 5- to 6-membered ring, and more preferably a 5-membered ring.

When the group formed by bonding R² and R³ is a cycloalkylidene group, the cycloalkylidene group may be fused with one or more other rings. Examples of the ring which may be fused with the cycloalkylidene group include a benzene ring, a naphthalene ring, a cyclobutane ring, a cyclopentane ring, a cyclohexane ring, a cycloheptane ring, a cyclooctane ring, a furan ring, a thiophene ring, a pyrrole ring, a pyridine ring, a pyrazine ring, and a pyrimidine ring.

Examples of suitable group among R² and R³ descried above include a group represented by the formula: -A¹-A². In the formula, A¹ is a straight chain alkylene group, and A² is an alkoxy group, a cyano group, a halogen atom, a halogenated alkyl group, a cyclic organic group, or an alkoxycarbonyl group.

The number of carbon atoms of the straight chain alkylene group for A¹ is preferably 1 to 10, and more preferably 1 to 6. When A² is an alkoxy group, the alkoxy group may be any one of straight chain and branched chain alkoxy groups, and preferably a straight chain alkoxy group. The number of carbon atoms of the alkoxy group is preferably 1 to 10, and more preferably 1 to 6. When A² is a halogen atom, a fluorine atom, a chlorine atom, a bromine atom, or an iodine atom is preferable, and a fluorine atom, a chlorine atom, or a bromine atom is more preferable. When A² is a halogenated alkyl group, the halogen atom included in the halogenated alkyl group is preferably a fluorine atom, a chlorine atom, a bromine atom, or an iodine atom, and more preferably a fluorine atom, a chlorine atom, or a bromine atom. The halogenated alkyl group may be any one of straight chain and branched chain halogenated alkyl groups, and preferably a straight chain halogenated alkyl group. When A² is a cyclic organic group, examples of the cyclic organic group are the same as the cyclic organic group possessed by R² and R³ as the substituent. When A² is an alkoxycarbonyl group, examples of the alkoxycarbonyl group are the same as the alkoxycarbonyl group possessed by R² and R³ as the substituent.

Suitable specific examples of R² and R³ include alkyl groups such as an ethyl group, an n-propyl group, an n-butyl group, an n-hexyl group, an n-heptyl group, and an n-octyl group; alkoxyalkyl groups such as a 2-methoxyethyl group, a 3-methoxy-n-propyl group, a 4-methoxy-n-butyl group, a 5-methoxy-n-pentyl group, a 6-methoxy-n-hexyl group, a 7-methoxy-n-heptyl group, a 8-methoxy-n-octyl group, a 2-ethoxyethyl group, a 3-ethoxy-n-propyl group, a 4-ethoxy-n-butyl group, a 5-ethoxy-n-pentyl group, a 6-ethoxy-n-hexyl group, a 7-ethoxy-n-heptyl group, and a 8-ethoxy-n-octyl group; cyanoalkyl groups such as a 2-cyanoethyl group, a 3-cyano-n-propyl group, a 4-cyano-n-butyl group, a 5-cyano-n-pentyl group, a 6-cyano-n-hexyl group, a 7-cyano-n-heptyl group, and a 8-cyano-n-octyl group; phenylalkyl groups such as a 2-phenylethyl group, a 3-phenyl-n-propyl group, a 4-phenyl-n-butyl group, a 5-phenyl-n-pentyl group, a 6-phenyl-n-hexyl group, a 7-phenyl-n-heptyl group, and a 8-phenyl-n-octyl group; cycloalkylalkyl groups such as a 2-cyclohexylethyl group, a 3-cyclohexyl-n-propyl group, a 4-cyclohexyl-n-butyl group, a 5-cyclohexyl-n-pentyl group, a 6-cyclohexyl-n-hexyl group, a 7-cyclohexyl-n-heptyl group, a 8-cyclohexyl-n-octyl group, a 2-cyclopentylethyl group, a 3-cyclopentyl-n-propyl group, a 4-cyclopentyl-n-butyl group, a 5-cyclopentyl-n-pentyl group, a 6-cyclopentyl-n-hexyl group, a 7-cyclopentyl-n-heptyl group, and a 8-cyclopentyl-n-octyl group; alkoxycarbonylalkyl groups such as a 2-methoxycarbonylethyl group, a 3-methoxycarbonyl-n-propyl group, a 4-methoxycarbonyl-n-butyl group, a 5-methoxycarbonyl-n-pentyl group, a 6-methoxycarbonyl-n-hexyl group, a 7-methoxycarbonyl-n-heptyl group, a 8-methoxycarbonyl-n-octyl group, a 2-ethoxycarbonylethyl group, a 3-ethoxycarbonyl-n-propyl group, a 4-ethoxycarbonyl-n-butyl group, a 5-ethoxycarbonyl-n-pentyl group, a 6-ethoxycarbonyl-n-hexyl group, a 7-ethoxycarbonyl-n-heptyl group, and a 8-ethoxycarbonyl-n-octyl group; and halogenated alkyl groups such as a 2-chloroethyl group, a 3-chloro-n-propyl group, a 4-chloro-n-butyl group, a 5-chloro-n-pentyl group, a 6-chloro-n-hexyl group, a 7-chloro-n-heptyl group, a 8-chloro-n-octyl group, a 2-bromoethyl group, a 3-bromo-n-propyl group, a 4-bromo-n-butyl group, a 5-bromo-n-pentyl group, a 6-bromo-n-hexyl group, a 7-bromo-n-heptyl group, a 8-bromo-n-octyl group, a 3,3,3-trifluoropropyl group, and a 3,3,4,4,5,5,5-heptafluoro-n-pentyl group.

Among groups mentioned above, groups suitable as R² and R³ are an ethyl group, an n-propyl group, an n-butyl group, an n-pentyl group, a 2-methoxyethyl group, a 2-cyanoethyl group, a 2-phenylethyl group, a 2-cyclohexylethyl group, a 2-methoxycarbonylethyl group, a 2-chloroethyl group, a 2-bromoethyl group, a 3,3,3-trifluoropropyl group, and a 3,3,4,4,5,5,5-heptafluoro-n-pentyl group.

Like R¹, examples of suitable organic group for R⁴ include an alkyl group, an alkoxy group, a cycloalkyl group, a cycloalkoxy group, a saturated aliphatic acyl group, an alkoxycarbonyl group, a saturated aliphatic acyloxy group, an optionally substituted phenyl group, an optionally substituted phenoxy group, an optionally substituted benzoyl group, an optionally substituted phenoxycarbonyl group, an optionally substituted benzoyloxy group, an optionally substituted phenylalkyl group, an optionally substituted naphthyl group, a naphthoxy group, an optionally substituted naphthoyl group, an optionally substituted naphthoxycarbonyl group, an optionally substituted naphthoyloxy group, an optionally substituted naphthylalkyl group, an optionally substituted heterocyclyl group, an optionally substituted heterocyclylcarbonyl group, an amino group substituted with one or more organic groups, a morpholin-1-yl group, and a piperazin-1-yl group. Specific examples of these groups are the same as those described for R¹. R⁴ is also preferably a cycloalkylalkyl group, a phenoxyalkyl group which may have a substituent on an aromatic ring, and a phenylthioalkyl group which may have a substituent on an aromatic ring. The substituent which may be possessed by a phenoxyalkyl group and phenylthioalkyl group is the same as the substituent which may be possessed by a phenyl group included in R¹.

Among organic groups, R⁴ is preferably an alkyl group, a cycloalkyl group, a phenyl group which may have a substituent or cycloalkylalkyl group, or a phenylthioalkyl group which may have a substituent on an aromatic ring. The alkyl group is preferably an alkyl group having 1 to 20 carbon atoms, more preferably, an alkyl group having 1 to 8 carbon atoms, particularly preferably, an alkyl group having 1 to 4 carbon atoms, and most preferably a methyl group. Among optionally substituted phenyl groups, a methylphenyl group is preferable and a 2-methylphenyl group is more preferable. The number of carbon atoms of the cycloalkyl group included in the cycloalkylalkyl group is preferably 5 to 10, more preferably 5 to 8, and particularly preferably 5 or 6. The number of carbon atoms of the alkylene group included in the cycloalkylalkyl group is preferably 1 to 8, more preferably 1 to 4, and particularly preferably 2. Among cycloalkylalkyl groups, a cyclopentylethyl group is preferable. The number of carbon atoms of the alkylene group which may have a substituent on an aromatic ring included in the phenylthioalkyl group, is preferably 1 to 8, more preferably 1 to 4, and particularly preferably 2. Among the phenylthioalkyl group which may have a substituent on an aromatic ring, a 2-(4-chlorophenylthio)ethyl group is preferable.

R⁴ is also preferably a group represented by -A³-CO—O-A⁴. A³ is a divalent organic group, preferably a divalent hydrocarbon group, and more preferably an alkylene group. A⁴ is a monovalent organic group, and preferably a monovalent hydrocarbon group.

When A³ is an alkylene group, alkylene group may be any one of straight chain and branched chain alkylene groups, and preferably a straight chain alkylene group. When A³ is an alkylene group, the number of carbon atoms of the alkylene group is preferably 1 to 10, more preferably 1 to 6, and particularly preferably 1 to 4.

Suitable examples of A⁴ include an alkyl group having 1 to 10 carbon atoms, an aralkyl group having 7 to 20 carbon atoms, and an aromatic hydrocarbon group having 6 to 20 carbon atoms. Suitable specific examples of A⁴ include a methyl group, an ethyl group, an n-propyl group, an isopropyl group, an n-butyl group, an isobutyl group, a sec-butyl group, an tert-butyl group, an n-pentyl group, an n-hexyl group, a phenyl group, a naphthyl group, a benzyl group, a phenethyl group, an α-naphthylmethyl group, and a β-naphthylmethyl group.

Suitable specific examples of the group represented by -A³-CO—O-A⁴ include a 2-methoxycarbonylethyl group, a 2-ethoxycarbonylethyl group, a 2-n-propyloxycarbonylethyl group, a 2-n-butyloxycarbonylethyl group, a 2-n-pentyloxycarbonylethyl group, a 2-n-hexyloxycarbonylethyl group, a 2-benzyloxycarbonylethyl group, a 2-phenoxycarbonylethyl group, a 3-methoxycarbonyl-n-propyl group, a 3-ethoxycarbonyl-n-propyl group, a 3-n-propyloxycarbonyl-n-propyl group, a 3-n-butyloxycarbonyl-n-propyl group, a 3-n-pentyloxycarbonyl-n-propyl group, a 3-n-hexyloxycarbonyl-n-propyl group, a 3-benzyloxycarbonyl-n-propyl group, and a 3-phenoxycarbonyl-n-propyl group.

While R⁴ has been described above, R⁴ is preferably a group represented by the following formula (R4-1) or (R4-2):

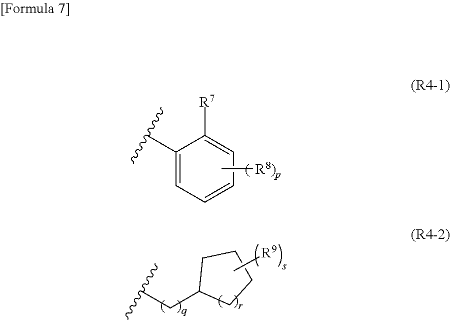

in which, in the formulas (R4-1) and (R4-2), R⁷ and R⁸ each are an organic group, p is an integer of 0 to 4; when R⁷ and R⁸ exist at adjacent positions on a benzene ring, R⁷ and R⁸ may be bonded to one another to form a ring; q is an integer of 1 to 8; r is an integer of 1 to 5; s is an integer of 0 to (r+3); and R⁹ is an organic group.

Examples of the organic group for R⁷ and R⁸ in the formula (R4-1) are the same as those in R¹. R⁷ is preferably an alkyl group or a phenyl group. When R⁷ is an alkyl group, the number of carbon atoms thereof is preferably 1 to 10, more preferably 1 to 5, particularly preferably 1 to 3, and most preferably 1. Namely, R⁷ is most preferably a methyl group. When R⁷ and R⁸ are bonded to form a ring, the ring may be either one of an aromatic ring or an aliphatic ring. Suitable examples of the group represented by the formula (R4-1) in which R⁷ and R⁸ form a ring include a naphthalen-1-yl group, a 1,2,3,4-tetrahydronaphthalen-5-yl group, and the like. In the above formula (R4-1), p is an integer of 0 to 4, preferably 0 or 1, and more preferably 0.

In the above formula (R4-2), R⁹ is an organic group. Examples of the organic group include the same group as the organic group described for R¹. Among the organic groups, an alkyl group is preferable. The alkyl group may be any one of straight chain and branched chain alkyl groups. The number of carbon atoms of the alkyl group is preferably 1 to 10, more preferably, 1 to 5, and particularly preferably 1 to 3. Preferable examples of R⁹ include a methyl group, an ethyl group, a propyl group, an isopropyl group, a butyl group, and the like. Among these, a methyl group is more preferable.

In the above formula (R4-2), r is an integer of 1 to 5, preferably an integer of 1 to 3, and more preferably 1 or 2. In the above formula (R4-2), s is 0 to (r+3), preferably an integer of 0 to 3, more preferably an integer of 0 to 2, and particularly preferably 0. In the above formula (R4-2), q is an integer of 1 to 8, preferably an integer of 1 to 5 more preferably an integer of 1 to 3, and particularly preferably 1 or 2.

In the formula (1), R⁵ is a hydrogen atom, an alkyl group having 1 to 11 carbon atoms which may have a substituent, or an optionally substituted aryl group. When R⁵ is an alkyl group, preferable examples of the substituent which may be possessed include a phenyl group, a naphthyl group, or the like. When R¹ is an aryl group, preferable examples of the substituent which may be possessed include an alkyl group having 1 to 5 carbon atoms, an alkoxy group, a halogen atom, or the like.

In the formula (1), preferable examples of R⁵ include a hydrogen atom, a methyl group, an ethyl group, an n-propyl group, an isopropyl group, an n-butyl group, a phenyl group, a benzyl group, a methylphenyl group, or a naphthyl group. Among these, a methyl group or a phenyl group is more preferable.

The content of the photopolymerization initiator as the component (B) is preferably 0.001 to 30 parts by mass, more preferably 0.1 to 20 parts by mass, and still more preferably 0.5 to 10 parts by mass, based on 100 parts by mass of the total solid content of the photosensitive composition. The content of the photopolymerization initiator as the component (B) is preferably 0.1 to 50% by mass, more preferably 0.5 to 30% by mass, and still more preferably 1 to 20 parts by mass, based on the sum total of the component (A) and the component (B). The content of the compound represented by the following formula (1) may be, for example, within a range of 1 to 100% by mass, and is preferably 50% by mass or more, and more preferably 70 to 100% by mass, based on the entire component (B).

The compound represented by the formula (1) in the component (B) may be used alone, or two or more compounds may be used in combination. When using two or more compounds, the following (i) to (iii) are preferable.

(i) combination of a compound in which R¹ is a hydrogen atom with a compound in which R¹ is a nitro group
(ii) combination of a compound in which R4 is the formula (R4-1) with a compound in which R4 is the formula (R4-2)
(iii) combination in which R4 is the formula (R4-1) or the formula (R4-2) with a compound in which R⁴ is an alkyl group having 1 to 4 carbon atoms
Among these, the above combination (i) is preferable in view of an improvement in properties such as sensitivity and transmittance of a cured product, and a combination satisfying (i) and (ii) or (iii) is more preferable.

A mixing ratio (mass ratio) of the respective compounds according to the above combinations (i) to (iii) may be appropriately adjusted according to properties such as objective sensitivity. For example, the mixing ratio is preferably 1:99 to 99:1, more preferably 10:90 to 90:10, and still more preferably 30:70 to 70:30.

Suitable specific examples of the compound represented by the formula (1) include the following compounds 1 to 41.

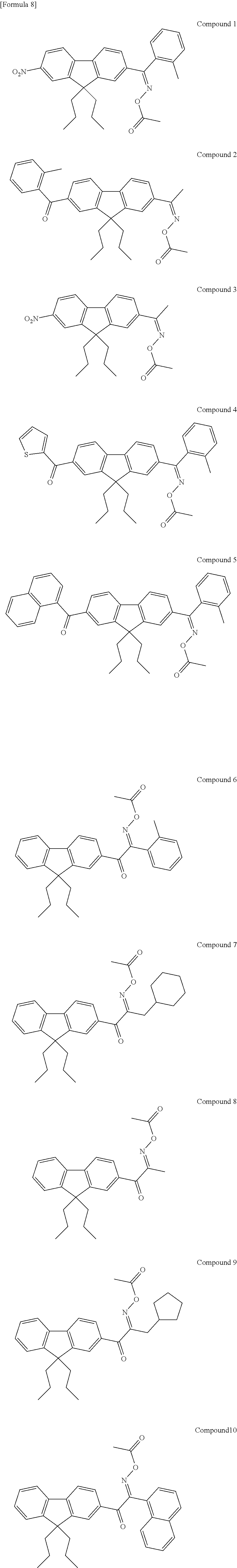

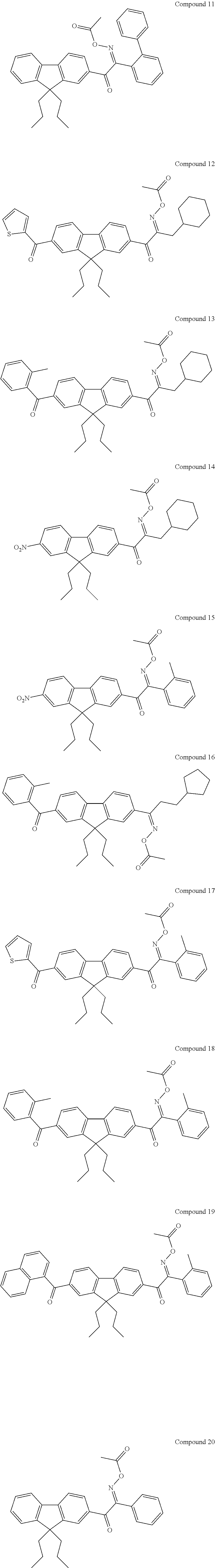

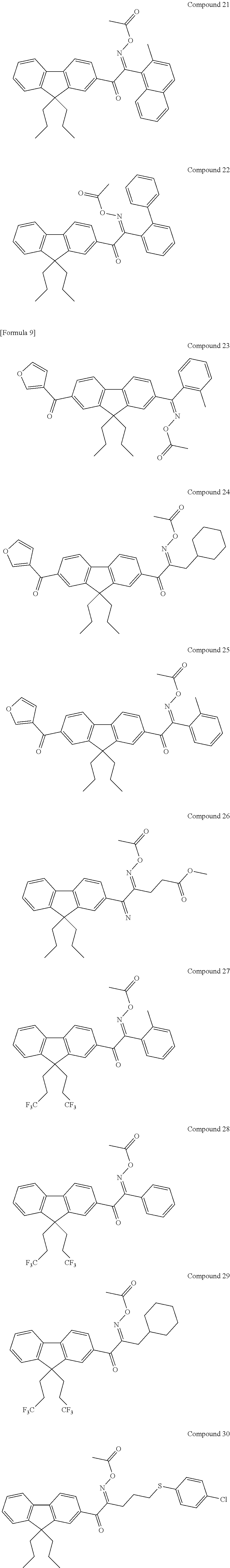

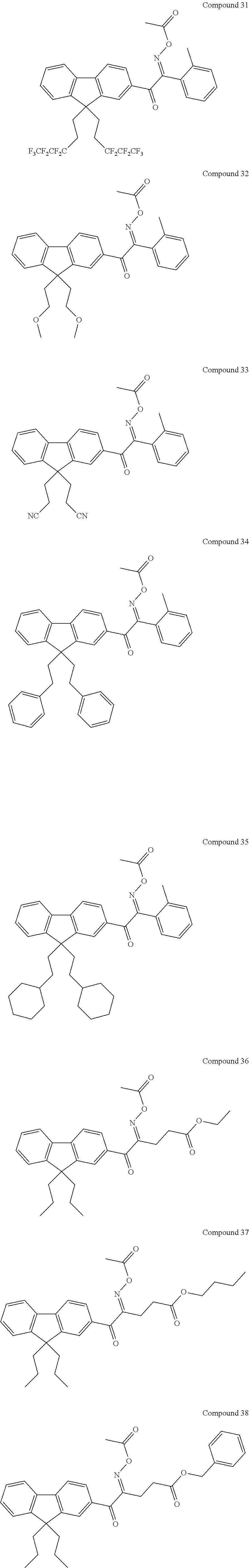

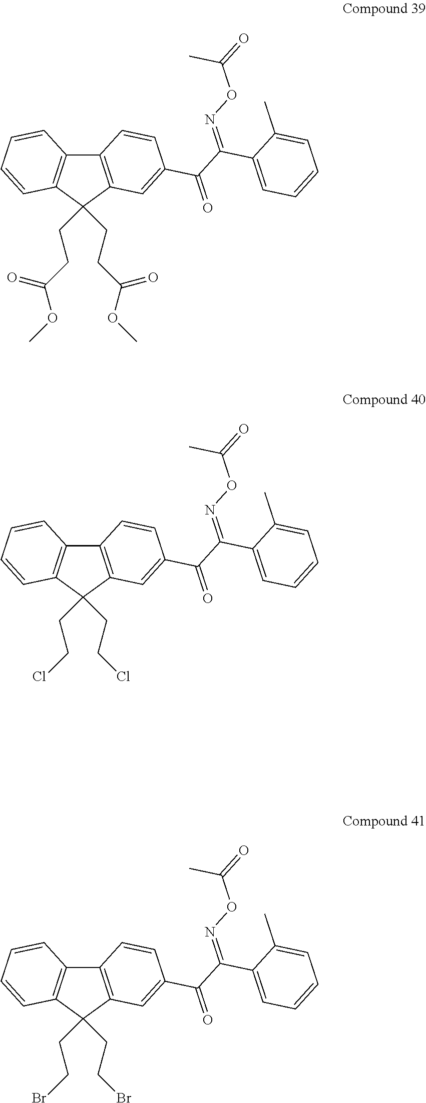 [SMILES: COC(=O)CCC1(CCC(=O)OC)c2ccccc2-c2ccc(C(=O)/C(=N/OC(C)=O)c3ccccc3C)cc21 ; CC(=O)O/N=C(/C(=O)c1ccc2c(c1)C(CCCl)(CCCl)c1ccccc1-2)c1ccccc1C ; CC(=O)O/N=C(/C(=O)c1ccc2c(c1)C(CCBr)(CCBr)c1ccccc1-2)c1ccccc1C]

### <(C) Alkali-Soluble Resin>

The photosensitive composition may or may not include, but preferably includes, as a resin other than resins used as the photopolymerizable compound (A), (C) an alkali-soluble resin. Alkali developability can be imparted to the photosensitive composition by mixing the alkali-soluble resin (C) in the photosensitive composition.

As used in the present specification, the alkali-soluble resin refers to a resin which forms a resin film having a film thickness of 1 μm on a substrate by a resin solution having a resin concentration of 20% by mass (solvent: propylene glycol monomethyl ether acetate), and which dissolves in a film thickness of 0.01 μm or more when immersed in an aqueous KOH solution having a concentration of 0.05% by mass for one minute.

Among alkali-soluble resins (C), a polymer of a monomer having an ethylenically unsaturated double bond is preferable since the polymer has excellent film formation properties and it is easy to adjust the properties of the resin by selection of the monomer. Examples of the monomer having an ethylenically unsaturated double bond include (meth)acrylic acid; (meth)acrylic acid ester; (meth)acrylic acid amide; crotonic acid; maleic acid, fumaric acid, citraconic acid, mesaconic acid, itaconic acid, and anhydrides of these dicarboxylic acids; allyl compounds such as allyl acetate, allyl caproate, allyl caprylate, allyl laurate, allyl palmitate, allyl stearate, allyl benzoate, allyl acetoacetate, allyl lactate, and allyloxyethanol; vinyl ethers such as hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethylene glycol vinyl ether, dimethylaminoethyl vinyl ether, diethylaminoethyl vinyl ether, butylaminoethyl vinyl ether, benzyl vinyl ether, tetrahydrofurfuryl vinyl ether, vinyl phenyl ether, vinyl tolyl ether, vinyl chlorophenyl ether, vinyl-2,4-dichlorophenyl ether, vinyl naphthyl ether, and vinyl anthranyl ether; vinyl esters such as vinyl butyrate, vinyl isobutyrate, vinyl trimethylacetate, vinyl diethyl acetate, vinyl valerate, vinyl caproate, vinyl chloroacetate, vinyl dichloroacetate, vinyl methoxyacetate, vinyl butoxyacetate, vinyl phenyl acetate, vinyl acetoacetate, vinyl lactate, vinyl-β-phenyl butyrate, vinyl benzoate, vinyl salicylate, vinyl chlorobenzoate, vinyl tetrachlorobenzoate, and vinyl naphthoate; styrenes such as styrene, methylstyrene, dimethylstyrene, trimethylstyrene, ethylstyrene, diethylstyrene, isopropylstyrene, butylstyrene, hexylstyrene, cyclohexylstyrene, decylstyrene, benzylstyrene, chloromethylstyrene, trifluoromethylstyrene, ethoxymethylstyrene, acetoxymethylstyrene, methoxystyrene, 4 methoxy-3-methylstyrene, dimethoxystyrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, and 4-fluoro-3-trifluoromethylstyrene, or styrene derivatives; and olefins such as ethylene, propylene, 1-butene, 1-pentene, 1-hexene, 3-methyl-1-butene, 3-methyl-1-pentene, 3-ethyl-1-pentene, 4-methyl-1-pentene, 4-methyl-1-hexene, 4,4-dimethyl-1-hexene, 4,4-dimethyl-1-pentene, 4-ethyl-1-hexene, 3-ethyl-1-hexene, 1-octene, 1-decene, 1-dodecene, 1-tetradecene, 1-hexadecene, 1-octadecene, and 1-eicosene.

The alkali-soluble resin (C), which is a polymer of a monomer having an ethylenically unsaturated double bond, usually includes a unit derived from an unsaturated carboxylic acid. Examples of the unsaturated carboxylic acid include (meth)acrylic acid; crotonic acid; and maleic acid, fumaric acid, citraconic acid, mesaconic acid, itaconic acid, and anhydrides of these dicarboxylic acids. There is no particular limitation on the amount of the unit derived from an unsaturated carboxylic acid included in the polymer of a monomer having an ethylenically unsaturated double bond to be used as the alkali-soluble resin, as long as the resin has desired alkali solubility. The amount of the unit deriaved from the unsaturated carboxylic acid in the resin used as the alkali-soluble resin is preferably 5 to 25% by mass, and more preferably 8 to 16% by mass, based on the mass of the resin.

Among the polymer of a monomer having an ethylenically unsaturated double bond, which is a polymer of one or more monomers selected from monomers exemplified above, a polymer of one or more monomers selected from (meth)acrylic acids and (meth)acrylic acid esters. A description will be made below on the polymer of one or more monomers selected from (meth)acrylic acids and (meth)acrylic acid esters.

There is no particular limitation on the (meth)acrylic acid ester to be used for preparation of the polymer of one or more monomers selected from (meth)acrylic acids and (meth)acrylic acid esters, as long as the object of the present invention is not inhibited, and the (meth)acrylic acid ester is appropriately selected from known (meth)acrylic acid esters.

Preferable examples of the (meth)acrylic acid ester include straight chain or branched chain alkyl (meth)acrylates such as methyl (meth)acrylate, ethyl (meth)acrylate, propyl (meth)acrylate, amyl (meth)acrylate, and t-octyl (meth)acrylate; aromatic (meth)acrylates such as phenyl (meth)acrylate, 4-methylphenyl (meth)acrylate, 3-methylphenyl (meth)acrylate, 2-methylphenyl (meth)acrylate, 4-hydroxyphenyl (meth)acrylate, 3-hydroxyphenyl (meth)acrylate, 2-hydroxyphenyl (meth)acrylate, naphthalen-1-yl (meth)acrylate, naphthalen-2-yl (meth)acrylate, 4-phenylphenyl (meth)acrylate, 3-phenylphenyl (meth)acrylate, and 2-phenylphenyl (meth)acrylate; aralkyl (meth)acrylates such as benzyl (meth)acrylate and phenethyl (meth)acrylate; chloroethyl (meth)acrylate, 2,2-dimethylhydroxypropyl (meth)acrylate, 2-hydroxyethyl (meth)acrylate, trimethylolpropane mono(meth)acrylate, and furfuryl (meth)acrylate; (meth)acrylic acid ester which has a group having an epoxy group; and (meth)acrylic acid ester which has a group having an alicyclic skeleton. Details of the (meth)acrylic acid ester which has a group having an alicyclic skeleton will be mentioned later.

Among the polymer of one or more monomers selected from (meth)acrylic acids and (meth)acrylic acid esters, a resin including a unit derived from a (meth)acrylic acid ester which has a group having an alicyclic skeleton is also preferable, since it is easy to form a resist pattern having excellent balance between heat resistance and flexibility by using the photosensitive composition.

In the (meth)acrylic acid ester which has a group having an alicyclic skeleton, a group having an alicyclic skeleton may be any one of a single ring and a polycyclic ring. Examples of the monocyclic alicyclic group include a cyclopentyl group, a cyclohexyl group, and the like. Examples of the polycyclic alicyclic group include a norbornyl group, an isobornyl group, a tricyclononyl group, a tricyclodecyl group, a tetracyclododecyl group, and the like.

Among the (meth)acrylic acid ester having an alicyclic skeleton, (meth)acrylic acid ester which has a group having an alicyclic hydrocarbon group includes compounds represented by the following formulas (c1-1) to (c1-8). Among these, compounds represented by the following formulas (c1-3) to (c1-8) are preferable, and a compound represented by the following formula (c1-3) or (c1-4) is more preferable.

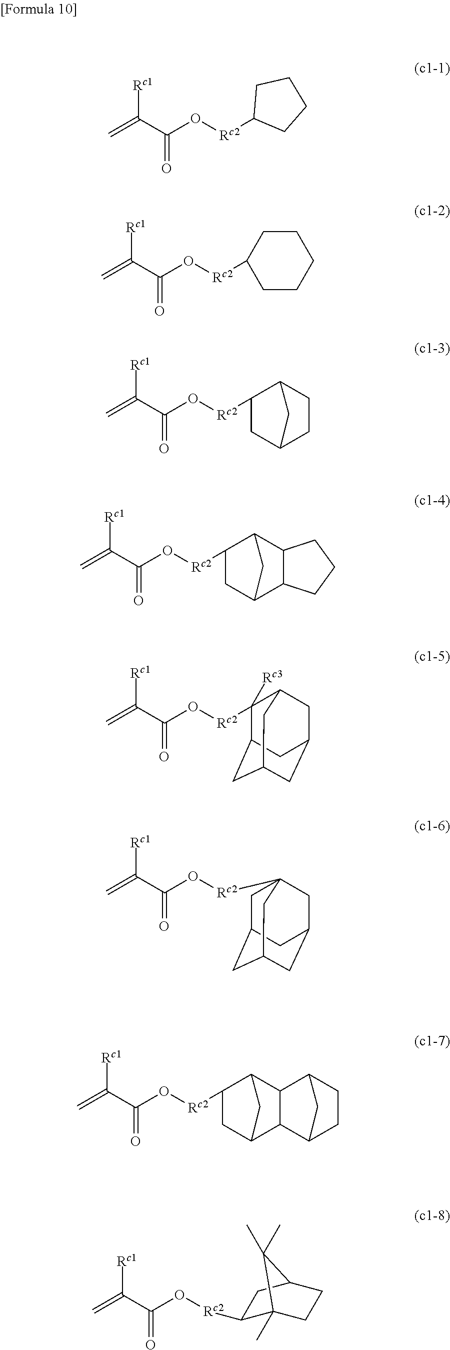

In the above formula, R^{c1} represents a hydrogen atom or a methyl group, R^{c2} represents a single bond or a divalent aliphatic saturated hydrocarbon group having 1 to 6 carbon atoms, and R^{c3} represents a hydrogen atom or an alkyl group having 1 to 5 carbon atoms. R^{c2} is preferably a single bond, or a straight chain or branched chain alkylene group, for example, a methylene group, an ethylene group, a propylene group, a tetramethylene group, an ethylethylene group, a pentamethylene group, or a hexamethylene group. R^{c3} is preferably a methyl group or an ethyl group.

When the polymer of one or more monomers selected from (meth)acrylic acids and (meth)acrylic acid esters is a resin including a unit derived from a (meth)acrylic acid ester which has a group having an alicyclic skeleton, the amount of the unit derived from the a (meth)acrylic acid ester which has a group having an alicyclic skeleton in the resin is preferably 5 to 95% by mass, more preferably 10 to 90% by mass, and still more preferably 30 to 70% by mass.

In the resin including a unit derived from (meth)acrylic acid and a unit derived from a (meth)acrylic acid ester having an alicyclic hydrocarbon group, the amount of the unit derived from (meth)acrylic acid in the resin is preferably 1 to 95% by mass, and more preferably 10 to 50% by mass. In the resin including a unit derived from (meth)acrylic acid and a unit derived from a (meth)acrylic acid ester having an alicyclic hydrocarbon group, the amount of the unit derived from a (meth)acrylic acid ester having an alicyclic epoxy group is preferably 1 to 95% by mass, and more preferably 10 to 70% by mass.

It is particularly easy to form a resist pattern with resist-free portions having a satisfactory rectangular sectional shape, the alkali-soluble resin (C) is preferably a polymer of a monomer having an ethylenically unsaturated double bond and including a unit having an aromatic group. Here, the aromatic group may be either an aromatic hydrocarbon group or an aromatic heterocyclic group, and is preferably an aromatic hydrocarbon group. As described above, the photosensitive composition according to the second aspect includes (C) an alkali-soluble resin, in which (C) the alkali-soluble resin is a polymer of a monomer having an unsaturated double bond and includes a unit derived from a monomer having an aromatic group.

The ratio of a unit derived from a monomer having an aromatic group to the total mass of the alkali-soluble resin (C) is preferably 5 to 95% by mass, and more preferably 30 to 95% by mass.

The polymer including a unit having an aromatic group is preferably a polymer (C-I) including a unit derived from an unsaturated carboxylic acid and a unit having an aromatic group. The polymer (C-I) is more preferably a polymer including a unit derived from (meth)acrylic acid and a unit having an aromatic group. A polymer (C-II) including a unit having a phenolic hydroxyl group is also preferable as a polymer of a monomer having an unsaturated double bond and including a unit having an aromatic group.

### (Polymer (C-I))

The polymer (C-I) includes a unit derived from an unsaturated carboxylic acid and a unit having an aromatic group. The polymer (C-I) includes a unit derived from an unsaturated carboxylic acid and therefore exhibits satisfactory alkali solubility and can impart flexibility to the thus formed resist pattern, and thus it is easy to suppress the generation of cracks in the resist pattern. Examples of the unsaturated carboxylic acid include (meth)acrylic acid; crotonic acid; maleic acid, fumaric acid, citraconic acid, mesaconic acid, itaconic acid, and anhydrides of these dicarboxylic acids. Among these, (meth)acrylic acid is preferable since it is easily available and exhibits satisfactory polymerization reactivity, and is easy to obtain the alkali-soluble resin (C) capable of preparing a photosensitive composition having excellent developability. The polymer (C-I) preferably includes a unit derived from a straight chain or branched chain alkyl (meth)acrylate and/or a unit derived from a (meth)acrylic acid ester which has a group having an alicyclic skeleton. In this case, because of particularly satisfactory flexibility of the polymer (C-I), it is easy to suppress the generation of cracks in the thus formed resist pattern. The straight chain or branched chain alkyl (meth)acrylate and the (meth)acrylic acid ester which has a group having an alicyclic skeleton will be mentioned later.

In the polymer including a unit derived from an unsaturated carboxylic acid and a unit having an aromatic group, examples of the monomer giving a unit having an aromatic group include vinyl ethers having an aromatic group, such as benzyl vinyl ether, vinyl phenyl ether, vinyl tolyl ether, vinyl chlorophenyl ether, vinyl-2,4-dichlorophenyl ether, vinyl naphthyl ether, and vinyl anthranyl ether; fatty acid esters having an aromatic group, such as vinyl phenyl acetate and vinyl-β-phenyl butyrate; aromatic (meth)acrylates such as phenyl (meth)acrylate, 4-methylphenyl (meth)acrylate, 3-methylphenyl (meth)acrylate, 2-methylphenyl (meth)acrylate, 4-hydroxyphenyl (meth)acrylate, 3-hydroxyphenyl (meth)acrylate, 2-hydroxyphenyl (meth)acrylate, naphthalen-1-yl (meth)acrylate, naphthalen-2-yl (meth)acrylate, 4-phenylphenyl (meth)acrylate, 3-phenylphenyl (meth)acrylate, and 2-phenylphenyl (meth)acrylate; aralkyl (meth)acrylates such as benzyl (meth)acrylate and phenethyl (meth)acrylate; aromatic vinyl carboxylates such as vinyl benzoate, vinyl salicylate, vinyl chlorobenzoate, vinyl tetrachlorobenzoate, and vinyl naphthoate; styrene or styrene derivatives, such as styrene, methylstyrene, dimethylstyrene, trimethylstyrene, ethylstyrene, diethylstyrene, isopropylstyrene, butylstyrene, hexylstyrene, cyclohexylstyrene, decylstyrene, benzylstyrene, chloromethylstyrene, trifluoromethylstyrene, ethoxymethylstyrene, acetoxymethylstyrene, methoxystyrene, 4 methoxy-3-methylstyrene, dimethoxystyrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, and 4-fluoro-3-trifluoromethylstyrene; and (meth)acrylic acid aromatic esters having an epoxy group, 4-glycidyloxyphenyl (meth)acrylate, 3-glycidyloxyphenyl (meth)acrylate, 2-glycidyloxyphenyl (meth)acrylate, 4-glycidyloxyphenylmethyl(meth)acrylate, 3-glycidyloxyphenylmethyl(meth)acrylate, and 2-glycidyloxyphenylmethyl(meth)acrylate.

Among these monomers having an aromatic group, preferred are styrene or styrene derivatives, such as styrene, methylstyrene, dimethylstyrene, trimethylstyrene, ethylstyrene, diethylstyrene, isopropylstyrene, butylstyrene, hexylstyrene, cyclohexylstyrene, decylstyrene, benzylstyrene, chloromethylstyrene, trifluoromethylstyrene, ethoxymethylstyrene, acetoxymethylstyrene, methoxystyrene, 4 methoxy-3-methylstyrene, dimethoxystyrene, chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, and 4-fluoro-3-trifluoromethylstyrene.

The resin including the unit derived from an unsaturated carboxylic acid and the unit having an aromatic group may include a unit other than these units. Examples of the unit other than the unit derived from an unsaturated carboxylic acid and the unit having an aromatic group include units derived from the above-described various monomers which do not correspond to an unsaturated carboxylic acid and a monomer having an aromatic group. A resin including a unit derived from an unsaturated carboxylic acid and a unit having an aromatic group preferably includes a unit derived from a straight chain or branched chain alkyl (meth)acrylate and/or a unit derived from a (meth)acrylic acid ester which has a group having an alicyclic skeleton. In this case, since the flexibility of the resin is particularly satisfactory, cracks in the resist pattern thus formed can be easily suppressed. Examples of a monomer giving a unit other than the unit derived from an unsaturated carboxylic acid and the unit having an aromatic group include (meth)acrylic acid ester; (meth)acrylic acid amide; allyl compounds such as allyl acetate, allyl caproate, allyl caprylate, allyl laurate, allyl palmitate, allyl stearate, allyl benzoate, allyl acetoacetate, allyl lactate, and allyloxyethanol; vinyl ethers such as hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethylene glycol vinyl ether, dimethylaminoethyl vinyl ether, diethylaminoethyl vinyl ether, butylaminoethyl vinyl ether, and tetrahydrofurfuryl vinyl ether; vinyl esters such as vinyl butyrate, vinyl isobutyrate, vinyl trimethylacetate, vinyl diethyl acetate, vinyl valerate, vinyl caproate, vinyl chloroacetate, vinyl dichloroacetate, vinyl methoxyacetate, vinyl butoxyacetate, vinyl acetoacetate, and vinyl lactate; and olefins such as ethylene, propylene, 1-butene, 1-pentene, 1-hexene, 3-methyl-1-butene, 3-methyl-1-pentene, 3-ethyl-1-pentene, 4-methyl-1-pentene, 4-methyl-1-hexene, 4,4-dimethyl-1-hexene, 4,4-dimethyl-1-pentene, 4-ethyl-1-hexene, 3-ethyl-1-hexene, 1-octene, 1-decene, 1-dodecene, 1-tetradecene, 1-hexadecene, 1-octadecene, and 1-eicosene.

Among the above-mentioned monomers giving a unit other than the unit derived from an unsaturated carboxylic acid and the unit having an aromatic group, a (meth)acrylic acid ester is preferable. Suitable examples of the (meth)acrylic acid ester will be described below.

Suitable examples of the (meth)acrylic acid ester include straight chain or branched chain alkyl (meth)acrylates such as methyl (meth)acrylate, ethyl (meth)acrylate, propyl (meth)acrylate, amyl (meth)acrylate, and t-octyl (meth)acrylate; chloroethyl (meth)acrylate, 2,2-dimethylhydroxypropyl (meth)acrylate, 2-hydroxyethyl (meth)acrylate, trimethylolpropane mono(meth)acrylate, and furfuryl (meth)acrylate; (meth)acrylic acid ester having a group having an epoxy group; and (meth)acrylic acid ester which has a group having an alicyclic skeleton.

Among (meth)acrylic acid esters, a (meth)acrylic acid ester which has a group having an alicyclic skeleton is also preferable since it is easy to form an excellent resist pattern having excellent balance between heat resistance and flexibility using a photosensitive composition.

In the (meth)acrylic acid ester which has a group having an alicyclic skeleton, a group having an alicyclic skeleton may be any one of a single ring and a polycyclic ring. Examples of the monocyclic alicyclic group include a cyclopentyl group, a cyclohexyl group, and the like. Examples of the polycyclic alicyclic group include a norbornyl group, an isobornyl group, a tricyclononyl group, a tricyclodecyl group, a tetracyclododecyl group, and the like.

Among the (meth)acrylic acid ester having an alicyclic skeleton, (meth)acrylic acid ester which has a group having an alicyclic hydrocarbon group includes compounds represented by the above-described formulas (c1-1) to (c1-8). Among these, compounds represented by the above-described formulas (c1-3) to (c1-8) are preferable, and a compound represented by the above-described formula (c1-3) or (c1-4) is more preferable.

The amount of the unit having an aromatic group in the polymer including the unit derived from an unsaturated carboxylic acid and the unit having an aromatic group is preferably 5 to 95% by mass more preferably 10 to 93% by mass, particularly preferably 20 to 90% by mass, and most preferably 50 to 85% by mass. If the content of the unit having an aromatic group in the polymer (C-I) is 5% by mass or more, it is easy to form a resist pattern having satisfactory heat resistance and shape. If the content of the unit having an aromatic group in the polymer (C-I) exceeds 95% by mass, the thus formed resist pattern may exhibit too high rigidity. If the rigidity of the resist pattern is too high, cracks are likely to be generated. The amount of the unit derived from an unsaturated carboxylic acid in the polymer including the unit derived from an unsaturated carboxylic acid and the unit having an aromatic group is preferably 1 to 95% by mass, and more preferably 5 to 50% by mass. When the polymer (C-I) includes the unit derived from an unsaturated carboxylic acid in the amount in the above range, it is easy to achieve a balance between the solubility of the photosensitive composition in a developing solution and the flexibility of the thus formed resist pattern.

### (Polymer (C-II) Including Unit Having Phenolic Hydroxyl Group)

As mentioned above, a polymer including a unit having a phenolic hydroxyl group is also preferably used as the alkali-soluble resin (C). Examples of a monomer giving a unit having a phenolic hydroxyl group include hydroxyphenyl (meth)acrylate and hydroxystyrene or hydroxystyrene derivatives.

Specific examples of hydroxyphenyl (meth)acrylate include 4-hydroxyphenyl (meth)acrylate, 3-hydroxyphenyl (meth)acrylate, and 2-hydroxyphenyl (meth)acrylate, and 4-hydroxyphenyl (meth)acrylate is preferable.

Preferred examples of hydroxystyrene or hydroxystyrene derivatives include hydroxystyrene, α-methylhydroxystyrene, α-ethylhydroxystyrene, and the like. These preferable hydroxystyrene or hydroxystyrene derivatives may be a para-substituent, a meta-substituent, or an ortho-substituent, and is preferably a para-substituent. Among hydroxystyrene or hydroxystyrene derivatives, p-hydroxystyrene is preferable.

The hydroxystyrene resin may include, in addition to the unit derived from hydroxystyrene or hydroxystyrene derivatives, various units. The unit other than the unit derived from hydroxystyrene or hydroxystyrene derivatives may be a unit derived from various monomers described about the alkali-soluble resin (C) including a unit derived from an unsaturated carboxylic acid.

Suitable examples of the monomer giving a unit other than the unit derived from hydroxystyrene or hydroxystyrene derivatives, which may be included in the hydroxystyrene resin, include a (meth)acrylic acid ester. Suitable examples of the (meth)acrylic acid ester include straight chain or branched chain alkyl (meth)acrylates such as methyl (meth)acrylate, ethyl (meth)acrylate, propyl (meth)acrylate, amyl (meth)acrylate, and t-octyl (meth)acrylate; aromatic (meth)acrylates having no hydroxyl group, such as phenyl (meth)acrylate, 4-methylphenyl (meth)acrylate, 3-methylphenyl (meth)acrylate, 2-methylphenyl (meth)acrylate, naphthalen-1-yl (meth)acrylate, naphthalen-2-yl (meth)acrylate, 4-phenylphenyl (meth)acrylate, 3-phenylphenyl (meth)acrylate, and 2-phenylphenyl (meth)acrylate; aralkyl (meth)acrylates such as benzyl (meth)acrylate and phenethyl (meth)acrylate; chloroethyl (meth)acrylate, 2,2-dimethylhydroxypropyl (meth)acrylate, 2-hydroxyethyl (meth)acrylate, trimethylolpropane mono(meth)acrylate, benzyl (meth)acrylate, and furfuryl (meth)acrylate; (meth)acrylic acid ester having a group having an epoxy group; and (meth)acrylic acid ester which has a group having an alicyclic skeleton.

The amount of the unit having a phenolic hydroxyl group in the polymer including the unit having a phenolic hydroxyl group is preferably 5 to 95% by mass, more preferably 10 to 93% by mass, particularly preferably 20 to 90% by mass, and most preferably 50 to 85% by mass. If the content of the unit having a phenolic hydroxyl group in the polymer (C-II) is 5% by mass or more, it is easy to form a resist pattern having satisfactory heat resistance and shape. If the content of the unit having a phenolic hydroxyl group in the polymer (C-II) exceeds 95% by mass, the thus formed resist pattern may exhibit too high rigidity. If the rigidity of the resist pattern is too high, cracks are likely to be generated. There prominently arises a problem that cracks are likely to be generated due to excess content of the unit having a phenolic hydroxyl group, when the polymer (C-II) includes a small amount (e.g., less than 5% by mass) of a unit imparting the flexibility to the resin, or includes no unit. The unit imparting the flexibility is, for example, at least one unit selected from the group consisting of a unit derived from an unsaturated carboxylic acid such as (meth)acrylic acid, unit derived from a straight chain or branched chain alkyl (meth)acrylate, and a unit derived from a (meth)acrylic acid ester which has a group having an alicyclic skeleton.

The polymer including a unit having a phenolic hydroxyl group preferably includes a unit derived from a straight chain or branched chain alkyl (meth)acrylate and/or a unit derived from a (meth)acrylic acid ester which has a group having an alicyclic skeleton, and more preferably a unit derived from a straight chain or branched chain alkyl (meth)acrylate, and more preferably a unit derived from a (meth)acrylic acid ester which has a group having an alicyclic skeleton. It is preferred that the polymer including a unit having a phenolic hydroxyl group includes a unit derived from a straight chain or branched chain alkyl (meth)acrylate and/or a unit derived from a (meth)acrylic acid ester which has a group having an alicyclic skeleton, since the flexibility of the resin increases, thus exerting the effect of preventing cracks. In the polymer including a unit having a phenolic hydroxyl group, the content of the unit derived from a straight chain or branched chain alkyl (meth)acrylate and the content of the unit derived from a (meth)acrylic acid ester which has a group having an alicyclic skeleton each independently is preferably 1 to 50% by mass, more preferably 5 to 40% by mass, and particularly preferably 10 to 30% by mass.

A mass average molecular weight (Mw: value in terms of polystyrene measured by gel permeation chromatography (GPC), the same shall apply in the present specification) of the alkali-soluble resin (C) is preferably 2,000 to 200,000, and more preferably 2,000 to 40,000. Within the above range, film formability of the photosensitive composition and developability after exposure tend to be well-balanced.

When the photosensitive composition includes the alkali-soluble resin (C), the content of the alkali-soluble resin (C) in the photosensitive composition is preferably 15 to 95% by mass, more preferably 35 to 85% by mass, and particularly preferably 50 to 70% by mass, in the solid content of the photosensitive composition.

### <Other Components>

The photosensitive composition may optionally contain various additives. Specific examples thereof include a solvent, a sensitizer, a curing accelerator, a photo-crosslinking agent, a photosensitizer, a dispersing agent, a filler, an adhesion accelerator, an antioxidant, an ultraviolet absorber, a flocculation inhibitor, thermopolymerization inhibitor, a defoaming agent, a surfactant, colorant, and the like.

Examples of the solvent used in the photosensitive composition according to the present invention include (poly)alkylene glycol monoalkyl ethers such as ethylene glycol monomethyl ether, ethylene glycol monoethyl ether, ethylene glycol-n-propyl ether, ethylene glycol mono-n-butyl ether, diethylene glycol monomethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, propylene glycol mono-n-propyl ether, propylene glycol mono-n-butyl ether, dipropylene glycol monomethyl ether, dipropylene glycol monoethyl ether, dipropylene glycol mono-n-propyl ether, dipropylene glycol mono-n-butyl ether, tripropylene glycol monomethyl ether, and tripropylene glycol monoethyl ether; (poly)alkylene glycol monoalkyl ether acetates such as ethylene glycol monomethyl ether acetate, ethylene glycol monoethyl ether acetate, diethylene glycol monomethyl ether acetate, diethylene glycol monoethyl ether acetate, propylene glycol monomethyl ether acetate, and propylene glycol monoethyl ether acetate; other ethers such as diethylene glycol dimethyl ether, diethylene glycol methyl ethyl ether, diethylene glycol diethyl ether, and tetrahydrofuran; ketones such as methyl ethyl ketone, cyclohexanone, 2-heptanone, and 3-heptanone; lactic acid alkyl esters such as methyl 2-hydroxypropionate and ethyl 2-hydroxypropionate; other esters such as ethyl 2-hydroxy-2-methylpropionate, methyl 3-methoxypropionate, ethyl 3-methoxypropionate, methyl 3-ethoxypropionate, ethyl 3-ethoxypropionate, ethoxyethyl acetate, hydroxyethyl acetate, methyl 2-hydroxy-3-methylbutanoate, 3-methoxybutyl acetate, 3-methyl-3-methoxybutyl acetate, 3-methyl-3-methoxybutyl propionate, ethyl acetate, n-propyl acetate, isopropyl acetate, n-butyl acetate, isobutyl acetate, n-pentyl formate, isopentyl acetate, n-butyl propionate, ethyl butyrate, n-propyl butyrate, isopropyl butyrate, n-butyl butyrate, methyl pyruvate, ethyl pyruvate, n-propyl pyruvate, methyl acetoacetate, ethyl acetoacetate, and ethyl 2-oxobutanoate; aromatic hydrocarbons such as toluene and xylene; and amides such as N-methylpyrrolidone, N,N-dimethylformamide, and N,N-dimethylacetamide. These solvents may be used alone, or two or more solvents may be used in combination.

Among these solvents, propylene glycol monomethyl ether, ethylene glycol monomethyl ether acetate, propylene glycol monomethyl ether acetate, propylene glycol monoethyl ether acetate, diethylene glycol dimethyl ether, diethylene glycol methyl ethyl ether, cyclohexanone, and 3-methoxybutyl acetate are preferable since they exhibit excellent solubility in the component (A), component (B), and component (C) mentioned above. It is particularly preferable to use propylene glycol monomethyl ether acetate and 3-methoxybutyl acetate. The solvent may be appropriately determined according to applications of the photosensitive composition. As an example, the amount of the solvent is about 50 to 900 parts by mass based on 100 parts by mass of the total solid content of the photosensitive composition.

Examples of the thermopolymerization inhibitor used in the photosensitive composition include hydroquinone, hydroquinone monoethyl ether, and the like. Examples of the defoaming agent include a silicone-based and a fluorine-based compound, and examples of the surfactant include anionic, cationic, and nonionic compounds, respectively.

### <Method for Preparing Photosensitive Composition>

A photosensitive composition is prepared by mixing the respective components mentioned above while stirring by a conventional method. Examples of the device which can be used when the respective components mentioned above are mixed while stirring include a dissolver, a homogenizer, a three-roll mill, and the like. After uniformly mixing the respective components, the thus obtained mixture may be further filtered through a mesh, a membrane filter, or the like.

### [Lamination Method]

The above-described photosensitive composition is laminated on a metal surface of the above-mentioned substrate having a metal surface to form a photosensitive layer. The photosensitive layer has a thickness of 80 μm or more, preferably 80 to 500 μm, and more preferably 120 to 300 μm. A method for laminating a photosensitive layer on a substrate is not particularly limited, and typically includes a method in which the above-mentioned photosensitive composition is coated on a substrate, and a method in which a dry film formed using the above-mentioned photosensitive composition is laminated on a substrate. Coating and lamination of a dry film will be described below.

### [Substrate]

A substrate is not particularly limited and conventionally known substrates can be used, and examples thereof include a substrate for electron components, a substrate with a given wiring pattern formed thereon, and the like. Examples of the substrate include substrates made of metals such as silicon, silicon nitride, titanium, tantalum, palladium, titanium tungsten, copper, chromium, iron, and aluminum, glass substrate, and the like. A substrate having a metal surface such as a wiring pattern is used as the substrate. Examples of the metal constituting the metal surface include copper, solder, chromium, aluminum, nickel, gold, and the like, and copper, gold, and aluminum are preferable, and copper is more preferable.

### [Coating]

It is possible to employ, as a method of coating a photosensitive composition on a substrate, methods such as a spin coating method, a slit coating method, a roll coating method, a screen printing method, and an applicator method. When it is difficult to form a photosensitive layer having a desired film thickness by single coating, the photosensitive layer may be formed by coating a plurality of times of two or more times.

The photosensitive layer is preferably subjected to prebaking. The prebaking conditions may vary depending on the type of each component in the photosensitive composition, the mixing ratio, the film thickness of the coating, and the like. Usually the conditions may involve a temperature of 70 to 170° C., and preferably 80 to 150° C. for a time period of about 2 to 60 minutes. When coating is performed a plurality of times, the photosensitive layer may be subjected to prebaking after coating a plurality of times, or may be subjected to prebaking after coating each time.

### [Dry Film]

The above-described photosensitive composition may be used in the form of a dry film. The dry film is produced by forming a photosensitive layer formed of the above-mentioned photosensitive composition on a base film.

The base film is preferably a base film having light transmission properties. Specific examples thereof include a polyethylene terephthalate (PET) film, a polypropylene (PP) film, a polyethylene (PE) film, and the like. In view of excellent balance between light transmission properties and breaking strength, a polyethylene terephthalate (PET) film is preferable.

When a photosensitive layer is formed on a base film, using an applicator, a bar coater, a wire bar coater, a roll coater, a curtain flow coater, or the like, a photosensitive composition is coated on a base film such that a film thickness after drying would be 80 μm or more, preferably 80 to 500 μm, and more preferably 120 to 300 μm, followed by drying.

In the dry film, a protective film may be further formed on the photosensitive layer. Examples of this protective film include a polyethylene terephthalate (PET) film, a polypropylene (PP) film, a polyethylene (PE) film, and the like.

By sticking the above-described dry film on the above-mentioned substrate, the photosensitive layer is laminated on the substrate. When it is difficult to prepare or obtain a dry film having a desired film thickness, plural dry films may be stuck on the substrate to form a photosensitive layer having a desired film thickness. In the same manner as in case where a photosensitive layer is formed by coating, a photosensitive layer formed by using a dry film is preferably subjected to prebaking.

### <Exposure Step>

The thus formed photosensitive layer is site-selectively irradiated (exposed) with actinic ray or radiation, for example, ultraviolet light or visible light having a wavelength of 300 to 500 nm through a negative mask capable of forming a pattern having a given shape.

Low pressure mercury lamps, high pressure mercury lamps, super high-pressure mercury lamps, metal halide lamps, argon gas lasers, etc. can be used for the light source of the radiation. The radiation includes microwaves, infrared rays, visible light, ultraviolet rays, X rays, γ rays, electron beams, proton beams, neutron beams, ion beams, and the like. The irradiation dose of the radiation may vary depending on the composition of the photosensitive composition, the film thickness of the photosensitive layer, and the like, and for example, the dose is preferably about 100 to 1,000 mJ/cm². The above-mentioned photosensitive composition has excellent sensitivity, so that it is easy to form a resist pattern having a desired shape at a low exposure dose even if the photosensitive layer has a large thickness.

### <Development Step>

The exposed photosensitive layer is developed in accordance with a conventionally known method and then insoluble portions are dissolved and removed to form a given resist pattern. The developing solution is appropriately selected according to the composition of the photosensitive composition. When the photosensitive composition contains an alkali-soluble component such as an alkali-soluble resin, it is possible to use, as the developing solution, an organic developing solution such as monoethanolamine, diethanolamine, or triethanolamine, or an aqueous solution of sodium hydroxide, potassium hydroxide, sodium carbonate, ammonia, or a quaternary ammonium salt.

The developing time may vary depending on the composition of the photosensitive composition, a film thickness of the photosensitive layer, and the like, and is usually 1 to 30 minutes. The method of the development may be any one of a liquid-filling method, a dipping method, a paddle method, a spray developing method, and the like. The development may be performed by dividing into plural times while replacing a developing solution.

After the development, washing with running water is performed for 30 to 90 seconds, followed by drying with an air gun, drying in an oven, or the like. In this way, a resist pattern can be produced.

In this way, in accordance with the above method, a resist pattern is formed on a metal surface of a substrate having the metal surface using the above-mentioned photosensitive composition, whereby, it is possible to form resist-free portions having a satisfactory rectangular sectional shape even in a thick resist pattern having a film thickness of 80 μm or more.

### «Method for Producing Plated Shaped Article»

The above-resist pattern is preferably used as a mold for formation of a plated shaped article. A method for producing a plated shaped article includes plating a substrate with a mold, including the above-mentioned resist pattern as a mold for formation of a plated shaped article, to form a plated shaped article in the mold. Namely, metal is filled into resist-free portions in the resist pattern by plating to form a plated shaped article.

When forming the substrate with a mold, the above-mentioned substrate is used as the substrate. In the same manner as in the above-mentioned method for forming a patterned cured film, except that the shape of resist-free portions in the resist pattern is designed corresponding to the shape of a plated shaped article, a substrate with a mold is produced.

It is possible to form a plated shaped article, for example, connecting terminals such as metal posts and bumps by plating and embedding conductors of metals into resist-free portions (portions removed by a developing solution) in a mold of a substrate with a mold formed by the above method. The plating method is not particularly limited and various conventionally known methods can be employed. In particular, solder plating, copper plating, gold plating, and nickel plating liquids are preferably used as the plating liquid. Finally, the remaining mold is removed using a stripping liquid, etc. in accordance with a normal method.

According to the above method for producing a plated shaped article, a plated shaped article is produced using a mold with resist-free portions having a satisfactory rectangular sectional shape formed by using the above-mentioned photosensitive composition having a specific composition, so that the thus obtained plated shaped article also has a satisfactory rectangular sectional shape.

### EXAMPLES

The present invention will be more specifically descried below by way of Examples, but the present invention is not limited to these Examples.

### <(A) Photopolymerizable Compound>

In Examples and Comparative Examples, the below-mentioned A1 and A2, and A3 which is dipentaerythritol hexaacrylate were used as (A) a photopolymerizable compound (component (A)).

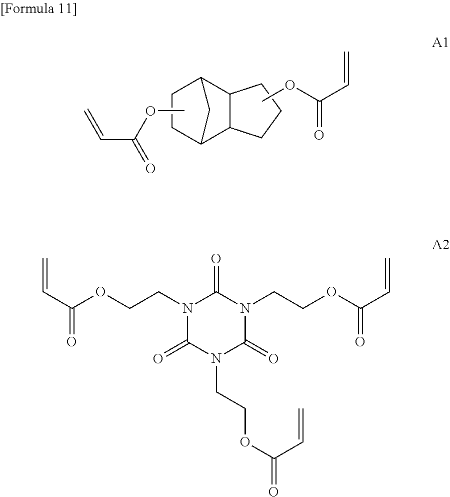

### <(B) Photopolymerization Initiator>

In Examples and Comparative Examples, the below-mentioned B1 to B4 were used as (B) a photopolymerization initiator (component (B)).

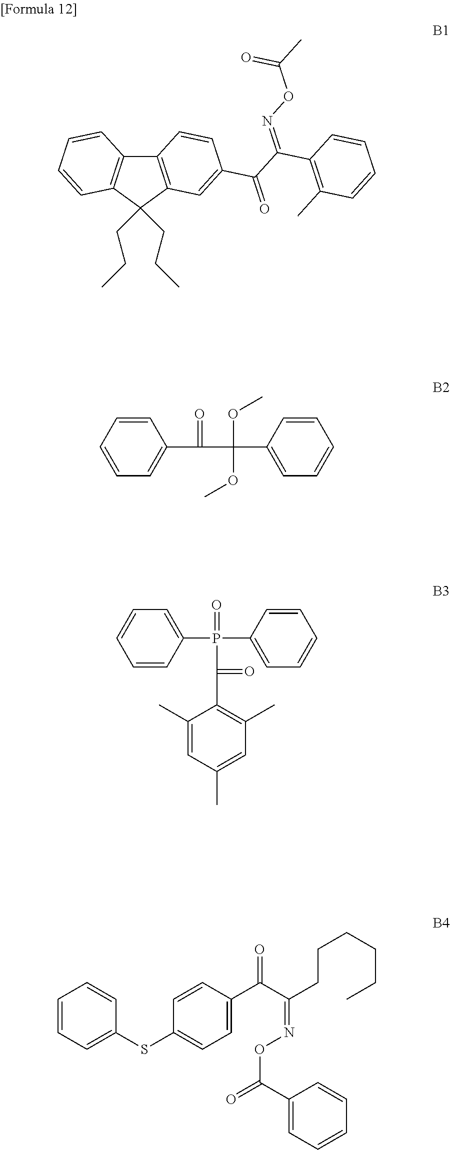 [SMILES: CCCC1(CCC)c2ccccc2-c2ccc(C(=O)/C(=N/OC(C)=O)c3ccccc3C)cc21 ; COC(OC)(C(=O)c1ccccc1)c1ccccc1 ; Cc1cc(C)c(C(=O)P(=O)(c2ccccc2)c2ccccc2)c(C)c1 ; CCCCCC/C(=N/OC(=O)c1ccccc1)C(=O)c1ccc(Sc2ccccc2)cc1]

### <(C) Alkali-Soluble Resin>

In Examples and Comparative Examples, the below-mentioned C1 to C4 were used as (C) an alkali-soluble resin (component (C)). In the following formula showing the structure of the alkali-soluble resin (C), the lower right numerical value of parentheses denotes the content (% by mass) of a unit in parentheses in a resin.

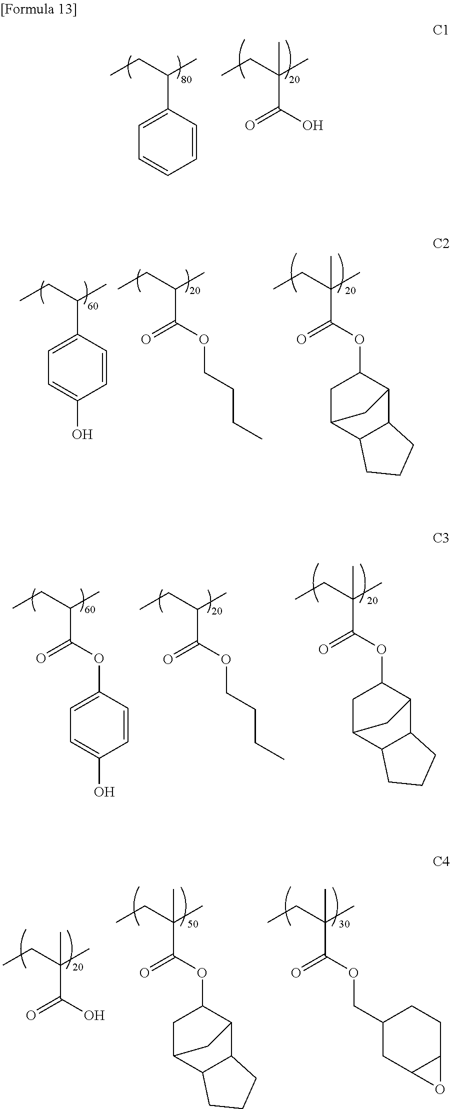

### <(S) Solvent>

In Examples and Comparative Examples, 3-methoxybutyl acetate (MA) and propylene glycol monomethyl ether acetate (PM) were used as (S) a solvent.

### Examples 1 to 9 and Comparative Examples 1 to 5

A component (A) of the type shown in Table 1, a component (B) of the type shown in Table 1, and a component (C) of the type shown in Table 1 were dissolved in a solvent (S) of a type shown in Table 1 such that the solid component concentration would be 70% by mass to obtain each of photosensitive compositions of Examples and Comparative Examples. The amount of the component (A) was 60 parts by mass, the amount of the component (B) was 12 parts by mass, and the amount of the component (C) was 100 parts by mass. Using the thus obtained photosensitive composition, resolution, EOP (optimum exposure dose required to reproduce a mask size), and sectional shape of resist-free portions in a resist pattern were evaluated in accordance with the following methods.

### <Evaluation of Resolution>

Using a spin coater, each of photosensitive compositions of Examples and Comparative Examples was coated on a copper substrate to form a photosensitive layer having a film thickness, at which a resist pattern having a film thickness of 120 μm can be formed, followed by prebaking at 120° C. for 600 seconds. Furthermore, using the same photosensitive composition, a photosensitive layer having a film thickness, at which a resist pattern having a film thickness of 120 μm can be formed, was formed on this photosensitive layer, followed by prebaking at 120° C. for 600 seconds to form a photosensitive layer having a film thickness, at which a resist pattern having a film thickness of 240 μm can be formed. After prebaking, using a test mask including via holes in size of 40, 60, 80, or 100 μm and an aligner Prisma GHI (manufactured by Ultratech, Inc.), exposure was performed while changing an exposure dose by 100 mJ/cm² in a range of 100 to 2,000 mJ/cm². Then, the substrate was placed on a hot plate and subjected to post-exposure baking (PEB) at 100° C. for 3 minutes. Thereafter, an aqueous 2.38% tetramethylammonium hydroxide solution (NMD-3, manufactured by Tokyo Ohka Kogyo Co., Ltd.) was dropped on the photosensitive layer, followed by being left to stand at 23° C. for 60 seconds. Then, development was performed by repeating this operation 10 times. After washing with running water and nitrogen blowing, a resist pattern having a film thickness of 240 μm was obtained. Regarding the photosensitive compositions of Comparative Examples 1 and 2, a photosensitive film was excessively dissolved during the development, thus failing to obtain a resist pattern. A minimum size (μm) of a pattern resolved when a pattern in size of 100 μm was exposed at an exposure dose, which enables printing corresponding to a given size of 100 μm, is shown in Table 1 as the evaluation results of the resolution.

### <Evaluation of EOP>

In the above-mentioned evaluation of the resolution, the exposure dose (mJ/cm²), at which a pattern in size of 100 μm is printed according to a size of 100 μm, is shown in Table 1 as the evaluation results of EOP.

### <Evaluation of Sectional Shape of Resist-Free Portions>

In the same manner as in the evaluation of the resolution, except that a test mask including via holes in size of 100 μm was used and exposure was performed at the exposure dose of the evaluation results of EOP, a resist pattern having a film thickness of 240 μm was obtained. Regarding the photosensitive compositions of Comparative Examples 1 and 2, a photosensitive film was excessively dissolved during the development, thus failing to obtain a resist pattern. A cross section of the thus obtained resist pattern was observed by a scanning electron microscope. Regarding a cross section of resist-free portions (holes), the size of the opening (top) (TCD (μm)) and the size (BCD (μm)) of the side bottom (bottom) of the substrate were measured, and then rectangularity of the cross section of holes was evaluated from the value of TCD/BCD in accordance with the following criteria. As the value of TCD/BCD becomes closer to 1, holes have more satisfactory rectangular sectional shape. The evaluation results of the sectional shape of resist-free portions are shown in Table 1.

A: The value of TCD/BCD is 0.9 or more and less than 1.2.
B: The value of TCD/BCD is 0.8 or more and less than 0.9.
C: The value of TCD/BCD is less than 0.8.

TABLE 1

| | | (B) | | | | | |
|---|---|---|---|---|---|---|---|
| | | Component | | | | | |
| | (A) | (Type/ | (C) | (S) | Resolution | EOP | Sectional |
| | Component | % by mass) | Component | Solvent | (μm) | (mJ/cm²) | shape |
| Example 1 | A1 | B1/2 | C1 | MA | 40 | 500 | A |
| Example 2 | A1 | B1/2 | C2 | MA | 40 | 400 | A |
| Example 3 | A1 | B1/2 | C3 | MA | 40 | 600 | A |
| Example 4 | A1 | B1/2 | C4 | MA | 80 | 1000 | B |
| Example 5 | A2 | B1/2 | C1 | MA | 60 | 500 | A |
| Example 6 | A3 | B1/2 | C1 | MA | 60 | 400 | A |
| Example 7 | A1 | B1/1 | C1 | MA | 40 | 700 | A |
| Example 8 | A1 | B1/3 | C1 | MA | 40 | 300 | A |
| Example 9 | A1 | B1/2 | C1 | PM | 40 | 500 | A |
| Comparative | A1 | B2/2 | C1 | MA | — | >2000 | — |
| Example 1 | | | | | | | |
| Comparative | A1 | B3/2 | C1 | MA | — | >2000 | — |
| Example 2 | | | | | | | |
| Comparative | A1 | B4/2 | C1 | MA | 100 | 2000 | C |
| Example 3 | | | | | | | |
| Comparative | A1 | B2/20 | C1 | MA | 100 | 2000 | C |
| Example 4 | | | | | | | |
| Comparative | A1 | B3/20 | C1 | MA | 100 | 2000 | C |
| Example 5 | | | | | | | |

As is apparent from Examples 1 to 9, a photosensitive composition including the photopolymerizable compound (A) and a compound represented by the formula (1) as the photopolymerization initiator (B) gives a resist pattern with resist-free portions having a satisfactory rectangular sectional shape at a low exposure dose even if a resist pattern has a large film thickness of 240 μm.

As is apparent from Examples 1 to 3 and 5 to 9, in which a photosensitive resin composition includes (C) an alkali-soluble resin having a unit including an aromatic group, the sectional shape of the resist-free portions provided in the resist pattern including the resist-free portions is a particularly satisfactory rectangular shape.

Meanwhile, as is apparent from Comparative Examples 1 to 5, when a photosensitive composition includes the photopolymerization initiator (B) of a structure which is not included in the formula (1), because of a large film thickness of 240 μm of a resist pattern, a resist pattern having a desired shape cannot be formed and a resist pattern with resist-free portions having a satisfactory rectangular sectional shape is hardly formed.

### Example 10 and Comparative Example 6

In Example 10, a dry film formed by using the photosensitive composition obtained in Example 1 was used for lamination of a photosensitive layer. Specifically, the photosensitive composition obtained in Example 1 was coated on a PET film using an applicator and then the coating film was dried at 100° C. to form a photosensitive layer having a film thickness, at which a resist pattern having a film thickness of 120 μm can be formed. In Comparative Example 6, a dry film formed by using the photosensitive composition obtained in Comparative Example 1 was used for lamination of a photosensitive layer. The method for forming a dry film used in Comparative Example 6 is the same as that used in Example 10.

Using a dry film formed of the photosensitive composition obtained in Example 1 or a dry film formed of the photosensitive composition obtained in Comparative Example 1, and a dry film laminator (EXL-1200HSF1-CE, manufactured by Teikoku Taping System Co., Ltd.), a photosensitive layer was stuck on a surface of a copper sputter wafer substrate under the conditions of a rate of 1 m/minute, a pressure of 0.5 MPa (G), a stage temperature of 80° C., and a roll temperature of 30° C. On the photosensitive layer stuck on the substrate surface, a dry film formed of the photosensitive composition obtained in Example 1 or a dry film formed of the photosensitive composition obtained in Comparative Example 1 were stuck again by the above method to form a photosensitive layer having a film thickness, at which a resist pattern having a film thickness of 240 μm can be formed. The photosensitive layer laminated on the substrate was subjected to prebaking under the conditions at 110° C. for 600 seconds. Using the substrate having the prebaked photosensitive layer thus formed using the dry film, resolution, EOP, and sectional shape of resist-free portions were evaluated in the same manner as in Example 1.

As a result, the evaluation results of Example 10 were the same as those of Example 1, and the evaluation results of Comparative Example 6 were the same as those of Comparative Example 1. As is apparent from these results, even if the photosensitive layer is formed by coating or formed by using a dry film, an influence is scarcely exerted on a sectional shape of a resist pattern and an exposure dose for formation of a resist pattern having a desired shape.

### Examples 11 to 13, Comparative Examples 7 to 9, Reference Example 1 and Reference Example 2

In Reference Example 1 and Examples 11 and 12, in the same manner as in Example 1, except for forming a photosensitive layer having a film thickness, at which the resist pattern shown in Table 2 is formed, a substrate having a prebaked photosensitive layer was obtained using the photosensitive composition used in Example 1. In Example 13, a photosensitive layer was formed by wet-on-wet double coating of a photosensitive composition in a film thickness, at which a resist pattern having a film thickness of 150 μm can be formed. In Reference Example 2 and Comparative Examples 7 and 8, in the same manner as in Example 1, except for forming a photosensitive layer having a film thickness, at which the resist pattern shown in Table 2 is formed, a substrate having a prebaked photosensitive layer was obtained using the photosensitive composition used in Comparative Example 4. In Comparative Example 9, a photosensitive layer was formed by wet-on-wet double coating of a photosensitive composition in a film thickness, at which a resist pattern having a film thickness of 150 μm can be formed.

Using the substrate having the prebaked photosensitive layer obtained in Examples, Comparative Examples, and Reference Examples, resolution, EOP, and sectional shape of resist-free portions were evaluated in the same manner as in Example 1. These evaluation results are shown in Table 2.

TABLE 2

| | Film thickness | Resolution | EOP | |
|---|---|---|---|---|
| | (μm) | (μm) | (mJ/cm²) | Sectional shape |
| Reference | 40 | 20 | 300 | A |
| Example 1 | | | | |
| Example 11 | 80 | 40 | 300 | A |
| Example 12 | 120 | 40 | 400 | A |
| Example 1 | 240 | 40 | 500 | A |
| Example 13 | 300 | 60 | 500 | A |
| Reference | 40 | 40 | 800 | A |
| Example 2 | | | | |
| Comparative | 80 | 60 | 1000 | A |
| Example 7 | | | | |
| Comparative | 120 | 100 | 2000 | C |
| Example 8 | | | | |
| Comparative | 240 | 100 | 2000 | C |
| Example 4 | | | | |
| Comparative | 300 | — | >2000 | — |
| Example 9 | | | | |

As is apparent from Reference Example 1, Example 1, and Examples 11 to 13, a photosensitive composition including the photopolymerizable compound (A) and a compound represented by the formula (1) as the photopolymerization initiator (B), can form a resist pattern with resist-free portions having a satisfactory rectangular sectional shape at a low exposure dose even if the film thickness of the resist pattern is changed in a range of 40 μm or more, particularly 80 μm or more.

Meanwhile, as is apparent from Reference Example 2, Comparative Example 4, and Comparative Examples 7 to 9, when the film thickness of a photosensitive composition including the photopolymerization initiator (B) having a structure which is not included in the formula (1) is comparatively small (e.g., 80 μm or less), high exposure dose is required even if a resist pattern with resist-free portions having a satisfactory rectangular sectional shape can be formed. It is also apparent that, when the film thickness is comparatively large (e.g., 120 μm or more), a resist pattern having a desired shape cannot be formed and a resist pattern with resist-free portions having a satisfactory rectangular sectional shape is hardly formed.

What is claimed is:

1. A method for forming a patterned cured film, the method comprising:
laminating a photosensitive layer formed from a photosensitive composition on a metal surface of a substrate having the metal surface;
exposing the photosensitive layer; and
developing the photosensitive layer after exposure, wherein
the photosensitive layer has a thickness of 80 μm or more,
the photosensitive composition comprises (A) a photopolymerizable compound, and (B) a photopolymerization initiator, and
the photopolymerization initiator (B) contains a compound represented by the following formula (1): 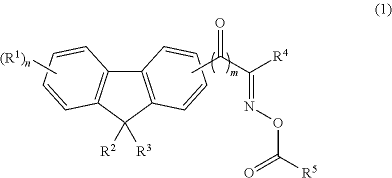
wherein R¹ is a hydrogen atom, a nitro group, or a monovalent organic group; R² and R³ each are an optionally substituted chain alkyl group, an optionally substituted cyclic organic group, or a hydrogen atom, R² and R³ may be bonded to one another to form a ring, R⁴ is a monovalent organic group, R⁵ is a hydrogen atom, an optionally substituted alkyl group having 1 to 11 carbon atom, or an optionally substituted aryl group, n is an integer of 0 to 4, and m is 0 or 1.

2. The method according to claim 1, wherein the photopolymerizable compound (A) includes a difunctional photopolymerizable compound.

3. The method according to claim 1, wherein the photosensitive layer is laminated on the metal surface using a dry film formed of the photosensitive composition.

4. A photosensitive composition comprising (A) a photopolymerizable compound, (B) a photopolymerization initiator, and (C) an alkali-soluble resin, wherein
the photopolymerization initiator (B) contains a compound represented by the following formula (1): 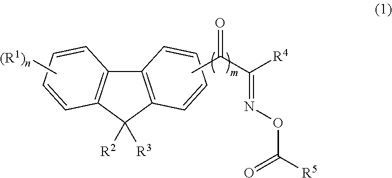
wherein R¹ is a hydrogen atom, a nitro group, or a monovalent organic group; R² and R³ each are an optionally substituted chain alkyl group, an optionally substituted cyclic organic group, or a hydrogen atom, R² and R³ may be bonded to one another to form a ring, R⁴ is a monovalent organic group, R⁵ is a hydrogen atom, an optionally substituted alkyl group having 1 to 11 carbon atom, or an optionally substituted aryl group, n is an integer of 0 to 4, and m is 0 or 1, and
the alkali-soluble resin (C) is a polymer of a monomer having an unsaturated double bond and includes a unit derived from a monomer having an aromatic group.

5. The photosensitive composition according to claim 4, wherein the photopolymerizable compound (A) includes a difunctional photopolymerizable compound.

6. The photosensitive composition according to claim 4, wherein the ratio of the unit derived from a monomer having an aromatic group to the total mass of the alkali-soluble resin (C) is 30 to 95% by mass.

7. A dry film formed from the photosensitive composition according to claim 4.

8. A method for forming a patterned cured film, the method comprising:
laminating a photosensitive layer formed of the photosensitive composition according to claim 4 on a metal surface of a substrate having the metal surface;
exposing the photosensitive layer; and
developing the photosensitive layer after exposure, wherein
the photosensitive layer has a thickness of 80 μm or more.

9. A method for forming a patterned cured film, the method comprising:
laminating a photosensitive layer formed of the photosensitive composition according to claim 4 on a metal surface of a substrate having the metal surface;
exposing the photosensitive layer; and
developing the photosensitive layer after exposure, wherein
the photosensitive layer has a thickness of 80 μm or more, and
the photosensitive layer is laminated on the metal surface using a dry film formed of the photosensitive composition.

10. The method according to claim 1, wherein the patterned cured film is a mold for formation of a plated shaped article.

11. The method according to claim 8, wherein the patterned cured film is a mold for formation of a plated shaped article.

12. A method for producing a plated shaped article, the method comprising plating the substrate with the mold formed by the method according to claim 10 to form a plated shaped article in the mold.

13. A method for producing a plated shaped article, the method comprising plating the substrate with the mold formed by the method according to claim 11 to form a plated shaped article in the mold.
